(19) United States
(12) Patent Application Publication
(10) Pub. No.: US 2026/0130134 A1
(43) Pub. Date: May 7, 2026

(54) SEMICONDUCTOR DEVICES AND METHOD FOR FORMING THE SAME

(71) Applicant: Taiwan Semiconductor Manufacturing Company Limited, Hsinchu (TW)

(72) Inventors: Kuo-Pin CHANG, Zhubei City (TW); Ching-En CHEN, Chiayi City (TW); Wei Ting HSIEH, Hsinchu (TW); Yu-Wei TING, Taipei City (TW); Kuo-Ching HUANG, Hsinchu City (TW); Hung-Ju LI, Hsinchu City (TW)

(21) Appl. No.: 18/934,305

(22) Filed: Nov. 1, 2024

(51) Int. Cl. H10N 79/00; H01L 23/66

(52) U.S. Cl. CPC H10N 79/00; H10W 44/20; H10W 44/209; H10W 44/248

(57) ABSTRACT

A phase change material switching circuit may be provided by forming a semiconductor circuit including a power amplifier and a low noise amplifier on a substrate; forming metal interconnect structures embedded in first dielectric material layers over the power amplifier and the low noise amplifier; forming a first phase change material (PCM) switch and a second PCM switch over the first dielectric material layers, wherein the first PCM switch includes a first electrode and a second electrode, and the second PCM switch includes a third electrode and a fourth electrode, wherein the second electrode is electrically connected to the third electrode to form a common electrical node; and electrically connecting a radio-frequency (RF) antenna to the common electrical node.

### BACKGROUND

Phase change material switches are useful devices that may mitigate against interference due to electromagnetic radiation, and may be used for various applications such as radio-frequency applications. The phase change material switches may provide electrical connection or electrical isolation in the path of radio-frequency signals depending on the resistivity state of a phase change material portion.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of an embodiment structure after formation of a semiconductor circuit, first metal interconnect structures, and first dielectric material layers according to an embodiment of the present disclosure.

FIG. 1B is a top-down view of the embodiment structure of FIG. 1A. The vertical plane A-A′ is the cut plane of the vertical cross-sectional view of FIG. 1A.

FIG. 2 is a vertical cross-sectional view of the embodiment structure after deposition of at least one metallic material layer according to an embodiment of the present disclosure.

FIG. 3A is a vertical cross-sectional view of the embodiment structure after patterning the at least one metallic material layer into a first metallic plate, a second metallic plate, a third metallic plate, a first heater element, and a second heater element according to an embodiment of the present disclosure.

FIG. 3B is a top-down view of the embodiment structure of FIG. 3A. The vertical plane A-A′ is the cut plane of the vertical cross-sectional view of FIG. 3A.

FIG. 4A is a vertical cross-sectional view of the embodiment structure after formation of a dielectric material layer according to an embodiment of the present disclosure.

FIG. 4B is a top-down view of the embodiment structure of FIG. 4A. The vertical plane A-A′ is the cut plane of the vertical cross-sectional view of FIG. 4A.

FIG. 5A is a vertical cross-sectional view of the embodiment structure after formation of thermally-conductive plates according to an embodiment of the present disclosure.

FIG. 5B is a top-down view of the embodiment structure of FIG. 5A. The vertical plane A-A′ is the cut plane of the vertical cross-sectional view of FIG. 5A.

FIG. 5C is a vertical cross-sectional view of a first alternative configuration of the embodiment structure after the processing steps of FIGS. 5A and 5B.

FIG. 6A is a vertical cross-sectional view of the embodiment structure after formation of a phase change material layer, a first cover dielectric layer, and a second cover dielectric layer according to an embodiment of the present disclosure.

FIG. 6B is a vertical cross-sectional view of the first alternative configuration of the embodiment structure after the processing steps of FIG. 6A.

FIG. 7A is a vertical cross-sectional view of the embodiment structure after patterning the second cover dielectric layer, the first cover dielectric layer, and the phase change material layer into a second cover dielectric plate, a first cover dielectric plate, and a phase change material portion according to an embodiment of the present disclosure.

FIG. 7B is a top-down view of the embodiment structure of FIG. 7A. The vertical plane A-A′ is the cut plane of the vertical cross-sectional view of FIG. 7A.

FIG. 7C is a vertical cross-sectional view of the first alternative configuration of the embodiment structure after the processing steps of FIGS. 7A and 7B.

FIG. 7D is a vertical cross-sectional view of a second alternative configuration of the embodiment structure after the processing steps of FIGS. 7A and 7B.

FIG. 7E is a top-down view of second configuration of the embodiment structure of FIG. 7D. The vertical plane D-D′ is the cut plane of the vertical cross-sectional view of FIG. 7D.

FIG. 8A is a vertical cross-sectional view of the embodiment structure after formation of second dielectric material layers, a metallic via structure, a metal pad structure, and a radio-frequency antenna according to an embodiment of the present disclosure.

FIG. 8B is a top-down view of the embodiment structure of FIG. 8A. The vertical plane A-A′ is the cut plane of the vertical cross-sectional view of FIG. 8A.

FIG. 8C is a vertical cross-sectional view of the embodiment structure of FIGS. 8A and 8B along the vertical plane C-C′ of FIG. 8B.

FIG. 8D is a vertical cross-sectional view of the first alternative configuration of the embodiment structure after the processing steps of FIGS. 8A-8C.

FIG. 8E is a vertical cross-sectional view of the first alternative configuration of the embodiment structure after the processing steps of FIGS. 8A-8C.

FIG. 9 is a top-down view of an alternative configuration of the embodiment structure after formation of various metal pad structures according to an embodiment of the present disclosure.

FIG. 10 is a perspective view of a portion of a PCM switch of the present disclosure.

FIG. 11A is a timing diagram for heater pulse signals and an RF transmission output signal during transition into a first switch state of a phase change material (PCM) switching circuit according to an embodiment of the present disclosure.

FIG. 11B is a schematic diagram representing a signal path while the PCM switching circuit is in the first switch state.

FIG. 12A is a timing diagram for heater pulse signals and an RF transmission input signal during transition into a second switch state of the PCM switching circuit according to an embodiment of the present disclosure.

FIG. 12B is a schematic diagram representing a signal path while the PCM switching circuit is in the second switch state.

FIG. 13A is a diagram illustrating the noise level in the input node of a low noise amplifier that is connected to the PCM switching circuit and the noise level at the input node of a low noise amplifier connected to a CMOS switching circuit.

FIG. 13B is a diagram comparing the device footprint and the switching power between a PCM switching circuit of the present disclosure and a conventional CMOS switching circuit.

FIG. 14 is a first flowchart that illustrates general processing steps for manufacturing a device structure according to embodiments of the present disclosure.

FIG. 15 is a second flowchart that illustrates general processing steps for manufacturing a device structure according to embodiments of the present disclosure.

### DETAILED DESCRIPTION

The following disclosure provides many different embodiments, or examples, for implementing various features of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein relate to semiconductor device structures and methods for forming the same. Specifically, various embodiments disclosed herein are directed to a single-pole double-throw (SPDT) phase change material (PCM) switching circuit for the purpose of radio-frequency (RF) signal switching. Various embodiments disclosed herein overcome the shortcomings of related SPDT switches by providing a simplified, low-power, and compact design that eliminates the need for shunt-cells while enhancing isolation and reducing parasitic capacitance. SPDT PCM switches use only a series connection of two PCM switches without using any shunt switches. This configuration not only simplifies the switching circuit but also reduces the overall area and power consumption of the switching circuit. The use of PCM switches provides superior signal isolation, effectively blocking signal leakage without the need for additional control circuits or devices.

During a manufacture process, a semiconductor circuit including a power amplifier (PA) and a low noise amplifier (LNA) may be formed on a substrate. First metal interconnect structures formed within first dielectric material layers may be formed over the PA and LNA. Two PCM switches are formed over first dielectric material layers. A common electrical node may be established by electrically shorting (i.e., electrically connecting) an electrode of a first PCM switch and an electrode of a second PCM switch. The common electrical node is connected to a radio-frequency (RF) antenna, facilitating efficient signal transmission and reception. The metallic electrode of the two PCM switches may be formed by depositing and patterning at least one metallic material layer into heater elements and metallic plates that function as electrodes. A phase change material layer may be deposited and patterned to form phase change material portions of the two PCM switches.

Various embodiments disclosed herein may comprise a semiconductor circuit with metal interconnect structures formed within dielectric layers and PCM switches configured to enhance performance and reduce footprint. The RF antenna may be electrically connected to the common electrical node of the PCM switches, enabling high signal isolation and low power operation. The various aspects and embodiments of the methods and structures of the present disclosure are described with reference to accompanying drawings.

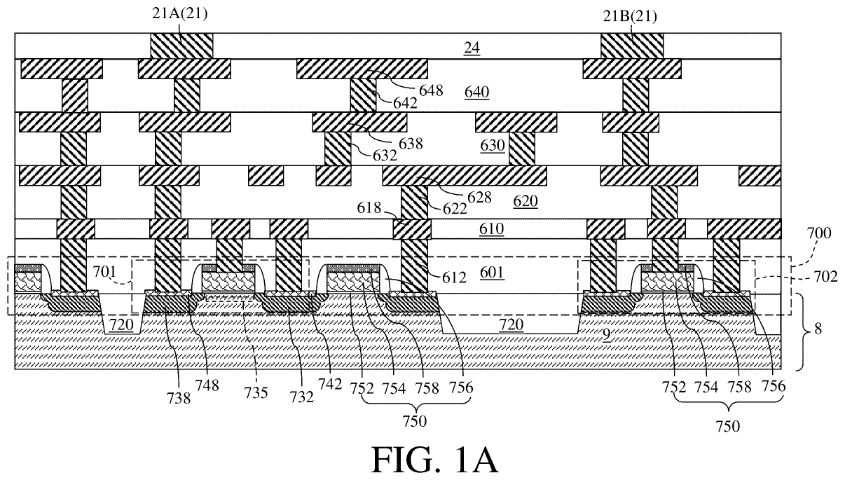

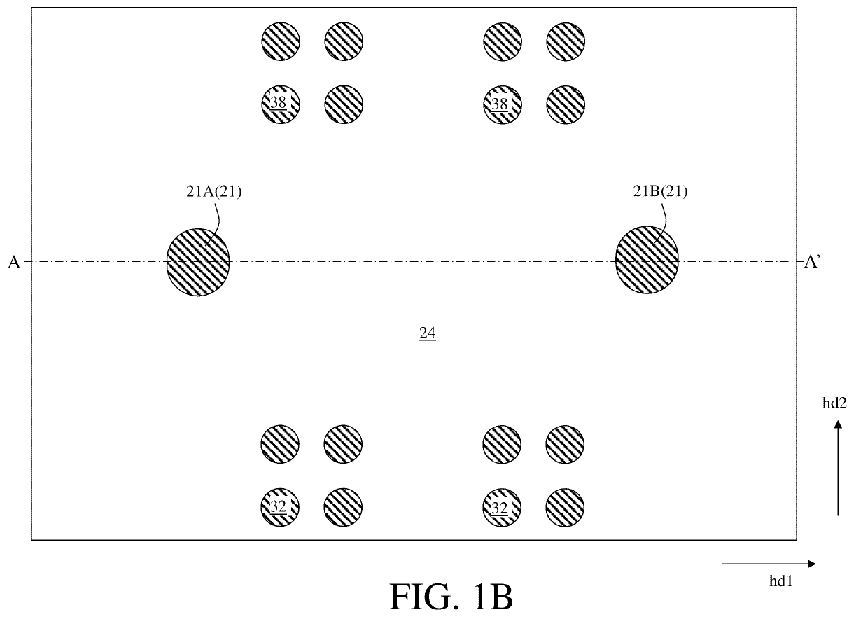

Referring to FIGS. 1A and 1B, an embodiment structure according to the present disclosure is illustrated. The embodiment structure includes a substrate 8, which may be a semiconductor substrate such as a silicon substrate. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720. A semiconductor circuit 700 may be formed over the top surface of the semiconductor material layer 9. The semiconductor circuit 700 may comprise a complementary metal oxide semiconductor (CMOS) circuit including p-type field effect transistors and n-type field effect transistors. For example, each field effect transistor may include a source region 732, a drain region 738, a semiconductor channel 735 that includes a surface portion of the substrate 8 extending between the source region 732 and the drain region 738, and a gate structure 750. The semiconductor channel 735 may include a single crystalline semiconductor material. Each gate structure 750 may include a gate dielectric layer 752, a gate electrode 754, a gate cap dielectric 758, and a dielectric gate spacer 756. A source-side metal-semiconductor alloy region 742 may be formed on each source region 732, and a drain-side metal-semiconductor alloy region 748 may be formed on each drain region 738. The devices formed on the top surface of the semiconductor material layer 9 may include complementary metal-oxide-semiconductor (CMOS) transistors and optionally additional semiconductor devices (such as resistors, diodes, capacitor structures, etc.), and are collectively referred to as semiconductor circuit 700.

One or more of the field effect transistors in the semiconductor circuit 700 may include a semiconductor channel 735 that contains a portion of the semiconductor material layer 9 in the substrate 8. In embodiments in which the semiconductor material layer 9 includes a single crystalline semiconductor material such as single crystalline silicon, the semiconductor channel 735 of each field effect transistor in the semiconductor circuit 700 may include a single crystalline semiconductor channel such as a single crystalline silicon channel. In one embodiment, a subset of the field effect transistors in the semiconductor circuit 700 may include a respective node that is subsequently electrically connected to a node of an energy harvesting device and/or to a battery structure to be subsequently formed.

In one embodiment, the substrate 8 may include a single crystalline silicon substrate, and the field effect transistors may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant.

According to an aspect of the present disclosure, the semiconductor circuit 700 comprises a power amplifier 701 that generates a radio-frequency (RF) signal at a sufficient signal strength for transmitting to a radio-frequency antenna. As used herein, a “power amplifier” refers to an amplifier that increases the power of a signal. Typically, the power amplifier is used in transmission paths to drive the antenna with a high-power signal. For example, the power that is transmitted out of the output node of the power amplifier 701 may be in a range from 1 Watt to 100 Watts, although lesser and greater powers may be transmitted from the output node of the power amplifier 701. As used herein, a “radio-frequency (RF) signal” refers to an electromagnetic wave with a frequency within the range of about 3 kHz to 300 GHz, used for wireless communication. In one embodiment, the drain region 738 of the power amplifier 701 may comprise an output node of the power amplifier 701. Further, the semiconductor circuit comprises a low noise amplifier (LNA) 702 that is configured to receive a radio-frequency signal from the radio-frequency antenna. As used herein, a “low noise amplifier” refers to an amplifier that amplifies weak signals with minimal added noise. Typically, the LNA is used in the reception path to amplify the received signal before it is processed by subsequent stages. For example, the amplitude of a radio-frequency signal that is transmitted to the input node of the low noise amplifier may be in a range from 1 microvolt to 100 millivolts, although lesser and greater amplitudes may also be used. In one embodiment, the gate electrode of the LNA may serve as the input node.

Additionally, the phase change material switches disclosed herein may also be utilized in other applications involving RF switches, such as MIMO (Multiple-Input Multiple-Output) radar systems and phase-shift RF circuits, where enhanced signal isolation and low power consumption are critical.

Various first dielectric material layers (601, 610, 620, 630, 640, 24) embedding various first metal interconnect structures (612, 618, 622, 628, 632, 638, 642, 648, 21, 32, 38) may be subsequently formed over the substrate 8 and the semiconductor circuit 700. In an illustrative example, the first dielectric material layers may include, for example, a contact-level dielectric material layer 601 that surrounds contact structures providing electrical connection to the source regions 732, the drain regions 738, and the gate electrodes 754, a first interconnect-level dielectric material layer 610, a second interconnect-level dielectric material layer 620, a third interconnect-level dielectric material layer 630, a fourth interconnect-level dielectric material layer 640, and a via-level dielectric material layer 24. The first metal interconnect structures may include device contact via structures 612 extending through the contact-level dielectric material layer 601 and contacting a respective component of the semiconductor circuit 700, first metal line structures 618 formed in the first interconnect-level dielectric material layer 610, first metal via structures 622 extending through a lower portion of the second interconnect-level dielectric material layer 620, second metal line structures 628 formed in an upper portion of the second interconnect-level dielectric material layer 620, second metal via structures 632 extending through a lower portion of the third interconnect-level dielectric material layer 630, third metal line structures 638 formed in an upper portion of the third interconnect-level dielectric material layer 630, third metal via structures 642 extending through a lower portion of the fourth interconnect-level dielectric material layer 640, fourth metal line structures 648 formed in an upper portion of the fourth interconnect-level dielectric material layer 640, and connection via structures (21, 32, 38) extending through the via-level dielectric material layer 24. While the present disclosure is described using an embodiment in which four levels of metal line structures are formed in first dielectric material layers, embodiments are expressly contemplated herein in which a lesser or greater number of levels of metal line structures are formed in the first dielectric material layers.

Each of the first dielectric material layers (601, 610, 620, 630, 640, 24) may include a dielectric material such as undoped silicate glass, a doped silicate glass, organosilicate glass, amorphous fluorinated carbon, porous variants thereof, or combinations thereof. Each of the first metal interconnect structures (612, 618, 622, 628, 632, 638, 642, 648, 21, 32, 38) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the first metal via structures 622 and the second metal line structures 628 may be formed as integrated line and via structures by a dual damascene process. Generally, any contiguous set of a metal line structure (628, 638, 648) and at least one underlying metal via structure (622, 632, 642) may be formed as an integrated line and via structure.

Generally, semiconductor devices (such as field effect transistors) may be formed on a substrate 8, and first metal interconnect structures (612, 618, 622, 628, 632, 638, 642, 648, 21, 32, 38) and first dielectric material layers (601, 610, 620, 630, 640, 24) over the semiconductor devices (such as the field effect transistors). The first metal interconnect structures (612, 618, 622, 628, 632, 638, 642, 648, 21, 32, 38) may be formed in the first dielectric material layers (601, 610, 620, 630, 640, 24), and may be electrically connected to the semiconductor devices.

The connection via structures (21, 32, 38) may be located at positions over which metallic plates of phase change material (PCM) radio-frequency (RF) switching circuit are to be subsequently formed. The connection via structures (21, 32, 38) may comprise signal node connection via structures 21 that are used to contact a subset of the metallic plates that are used as signal nodes of the PCM RF switching circuit, first heater connection via structures 32 that are used to contact a respective first wide end of metallic plates having a middle strip portion and used as a heater element, and second heater connection via structures 38 that are used to contact a respective second wide end of the metallic plates. The signal node connection via structures 21 may comprise a first signal node connection via structure 21A that is used to contact a signal node of a first (PCM) switch that is used as a signal path for a high-power RF signal from the output node of the power amplifier 701, and a second signal node connection via structure 21B that is used to contact a signal node of a second (PCM) switch that is used as a signal path for a low-power RF signal from an RF antenna to the input node of the low noise amplifier 702.

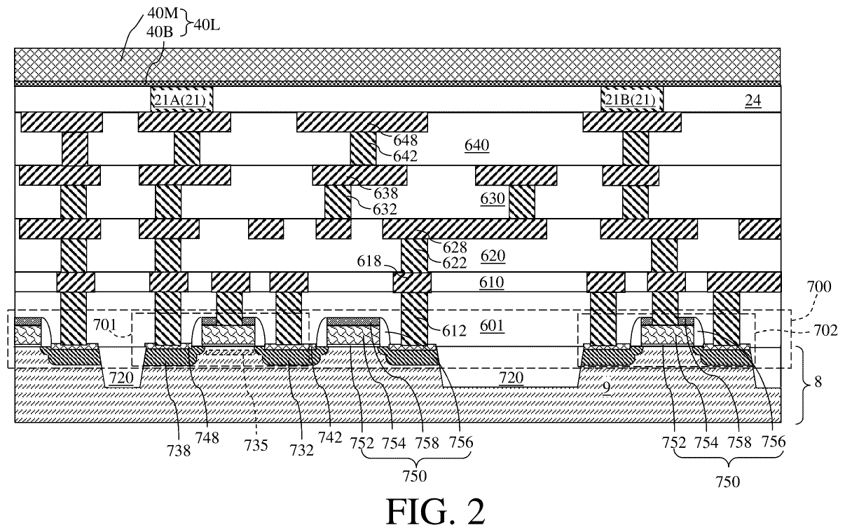

Referring to FIG. 2, at least one metallic material layer 40L may be deposited over the via-level dielectric material layer 24. Generally the at least one metallic material layer 40L may be deposited over the topmost surface of the first dielectric material layers (601, 610, 620, 630, 640, 24). In one embodiment, the at least one metallic material layer 40L comprises at least one metallic material that may withstand an elevated temperature that is sufficiently high to induce melting of a phase change material.

In one embodiment, the at least one metallic material layer 40L may comprise at least one metallic material that is selected from tungsten, tantalum, molybdenum, niobium, rhenium, tungsten nitride, tantalum nitride, titanium nitride, and molybdenum nitride, copper, aluminum gold, silver, platinum, and aluminum nitride. In one embodiment, the at least one metallic material layer 40L may comprise a metallic barrier material layer 40B and a main metallic layer 40M. The metallic barrier material layer 40B may consist essentially of a metallic nitride material that is selected from tungsten nitride, tantalum nitride, titanium nitride, and molybdenum nitride. The main metallic layer 40M may comprise a metal that is selected from tungsten, tantalum, molybdenum, niobium, rhenium, copper, aluminum gold, silver, platinum, and aluminum nitride. In a non-limiting illustrative example, the at least one metallic material layer 40L may comprise a metallic barrier material layer 40B including titanium nitride having a melting point of 2,930 degrees Celsius, and a main metallic layer 40M including tungsten having a melting point of 3,422 degrees Celsius.

Generally, the at least one metallic material layer 40L may be deposited by physical vapor deposition (PVD) and/or chemical vapor deposition (CVD). The thickness of the at least one metallic material layer 40L may be in a range from 30 nm to 300 nm, such as from 60 nm to 150 nm, although lesser and greater thicknesses may also be used.

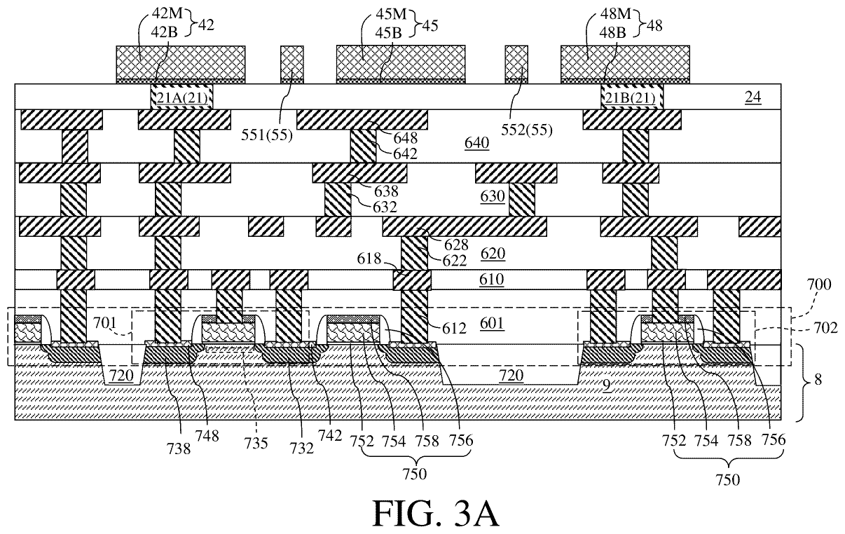

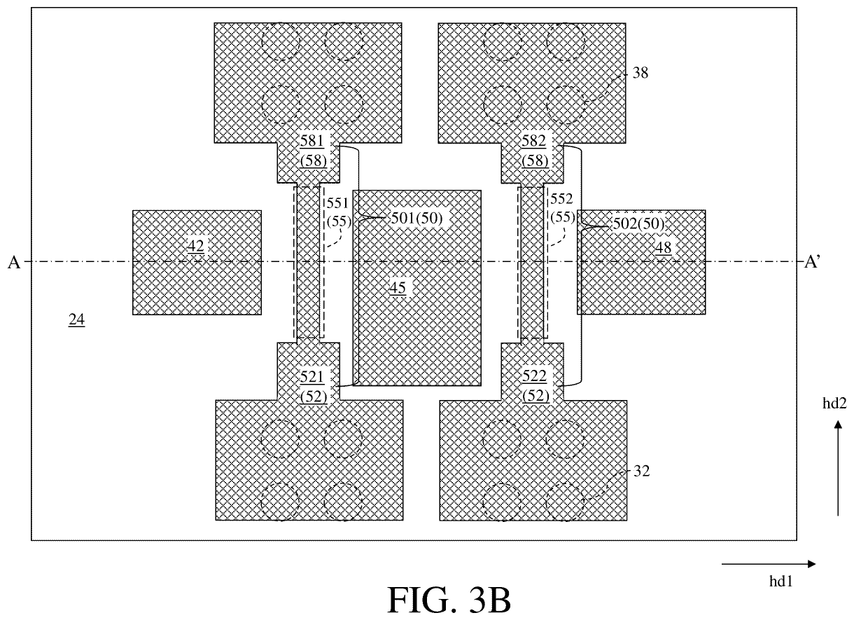

Referring to FIGS. 3A and 3B, an etch mask layer (such as a patterned photoresist layer) may be applied over the at least one metallic material layer 40L, and may be lithographically patterned to form a patterned etch mask layer (not illustrated). An etch process (such as a reactive ion etch process) may be performed to transfer the pattern in the patterned etch mask layer through the at least one metallic material layer 40L. The pattern in the patterned etch mask layer may be selected such that patterned remaining portions of the at least one metallic material layer 40L comprises a first heater element 501 for a first PCM RF switch, a second heater element 502 for a second PCM RF switch, a first electrode and a second electrode for the first PCM RF switch, and a second electrode for the second PCM RF switch. In one embodiment, the second electrode of the first (PCM) switch and the third electrode of the second (PCM) switch may comprise a same structure.

An anisotropic etch process may be performed to transfer the pattern in the etch mask layer though the at least one metallic material layer 40L. The at least one metallic material layer 40L may be patterned into a first metallic plate 42, a second metallic plate 45, a third metallic plate 48, a first heater element 501, and a second heater element 502. The first heater element 501 is formed between the first metallic plate 42 and the second metallic plate 45, and the second heater element 502 is formed between the second metallic plate 45 and the third metallic plate 48. Each of the first metallic plate 42, the second metallic plate 45, the third metallic plate 48, the first heater element 501, and the second heater element 502 comprises a respective patterned portion of the at least one metallic material layer 40L, and may comprise a respective patterned portion of the optional metallic barrier material layer 40B and the main metallic layer 40M. The etch mask layer may be subsequently removed, for example, by ashing.

Generally, patterned portions of the at least one metallic material layer 40L comprise a first heater element 501, a second heater element 502, the first electrode (which may comprise a first metallic plate 42), the second electrode (which may comprise a second metallic plate 45), the third electrode (comprising the second metallic plate 45), and the fourth electrode (which may comprise a third metallic plate 48). The first heater element 501, the second heater element 502, the first metallic plate 42, the second metallic plate 45, and the third metallic plate 48 may comprise a same set of at least one metallic material, and may have the same thickness.

According to an aspect of the present disclosure, the first metallic plate 42 may be electrically connected to an output node (such as a drain region 738) of the power amplifier 701, and the third metallic plate 48 may be electrically connected to an input node (such as a gate electrode 754) of the low noise amplifier 702.

Each heater element 50 comprises a strip portion 55 having a narrow uniform width; a first terminal portion 52 adjoined to a first end of the strip portion 55; and a second terminal portion 58 adjoined to a second end of the strip portion 55 and laterally spaced from the first terminal portion 52. For example, the heater elements 50 may comprise the first heater element 501 located between the first metallic plate 42 and the second metallic plate 45, and the second heater element 502 located between the second metallic plate 45 and the third metallic plate 48. The first heater element 501 may comprise a first-heater strip portion 551 having a narrow uniform width; a first-heater first terminal portion 521 adjoined to a first end of the first-heater strip portion 551; and a first-heater second terminal portion 581 adjoined to a second end of the first-heater strip portion 551. The second heater element 502 may comprise a second-heater strip portion 552 having a narrow uniform width; a second-heater first terminal portion 522 adjoined to a first end of the second-heater strip portion 552; and a second-heater second terminal portion 582 adjoined to a second end of the second-heater strip portion 552. In one embodiment, each strip portion 55 may have a narrow uniform width along a first horizontal direction hd1 and may laterally extend along a second horizontal direction hd2 that is perpendicular to the first horizontal direction hd1; and each second terminal portion 58 of a heater element 50 may laterally spaced from the first terminal portion 52 of the respective heater element 50 along the second horizontal direction hd2.

One of the first-heater first terminal portion 521 and the first-heater second terminal portion 581 may be connected to an output node of a first programming transistor located within the semiconductor circuit 700 and configured to generate electrical current pulses for programming a first PCM switch to be subsequently formed, and another of the first-heater first terminal portion 521 and the first-heater second terminal portion 581 may be electrically grounded. One of the second-heater first terminal portion 522 and the second-heater second terminal portion 582 may be connected to an output node of a second programming transistor located within the semiconductor circuit 700 and configured to generate electrical current pulses for programming a second PCM switch to be subsequently formed, and another of the second-heater first terminal portion 522 and the second-heater second terminal portion 582 may be electrically grounded.

The uniform width of each strip portion 55 along the first horizontal direction may be a critical dimension, i.e., the smallest dimension that may be printed using a single lithographic exposure with the lithography tool used to pattern the etch mask layer (such as the patterned photoresist layer). For example, the uniform width of the strip portion 55 may be in a range from 10 nm to 60 nm, such as from 20 nm to 40 nm, although lesser and greater dimensions may also be used. The ratio of the length of the strip portion 55 to the width of the strip portion 55 may be in a range from 3 to 60, such as from 6 to 30, although lesser and greater ratios may also be used.

Each of the first terminal portion 52 and the second terminal portion 58 may comprise a respective pad region, which may have a shape of a respective rectangle or a rounded rectangle. Each pad region may be adjoined to the strip portion 55 by an respective intermediate region having a lesser width along the first horizontal direction hd1 than the pad region. Each intermediate region may have a shape of a respective rectangle or a respective trapezoid. The first terminal portion 52 is adjoined to a first end of the strip portion 55, and the second terminal portion 58 is adjoined to a second end of the strip portion 55.

In one embodiment, the first-heater strip portion 551 of the first heater element 501 laterally extends between the first metallic plate 42 and the second metallic plate 45 along the second horizontal direction hd2; and the second-heater strip portion 552 of the second heater element 502 laterally extends between the second metallic plate 45 and the third metallic plate 48 along the second horizontal direction hd2. Each of the first metallic plate 42, the second metallic plate 45, and the third metallic plate 48 may have a respective rectangular shape. The width of each of the first metallic plate 42, the second metallic plate 45, and the third metallic plate 48 along the second horizontal direction hd2 may be in a range from 50% to 96%, such as from 70% to 90%, of the length of the strip portion 55 of each heater element 50. The length of each of the first metallic plate 42, the second metallic plate 45, and the third metallic plate 48 along the first horizontal direction hd1 may be in a range from 50% to 300% of the width of the respective one of the first metallic plate 42, the second metallic plate 45, and the third metallic plate 48 along the second horizontal direction hd2, although lesser and greater lengths may also be used.

In one embodiment, the top surfaces of the heater elements 50, the first metallic plate 42, the second metallic plate 45, and the third metallic plate 48 may be formed within a first horizontal plane. The bottom surface of the heater elements 50, the first metallic plate 42, the second metallic plate 45, and the third metallic plate 48 may be formed within a second horizontal plane that includes the top surface of the via-level dielectric material layer 24.

The width of the strip portion 55 of each heater element 50 along the first horizontal direction hd1 may be uniform throughout. In one embodiment, the width of the strip portion 55 of each heater element 50 along the first horizontal direction hd1 may be in a range from 10 nm to 100 nm, such as from 20 nm to 60 nm, although lesser and greater widths may also be used. The lateral separation distance between neighboring pairs of metallic plates among the first metallic plate 42, the second metallic plate 45, and the third metallic plate 48 may be in a range from 2 times the width of the strip portion 55 to 10 times the width of the strip portion 55, such as from 3 times the width of the strip portion 55 to 5 times the width of the strip portion 55. Each strip portion 55 is laterally spaced from neighboring metallic plates (42, 45, 48) by a respective gap.

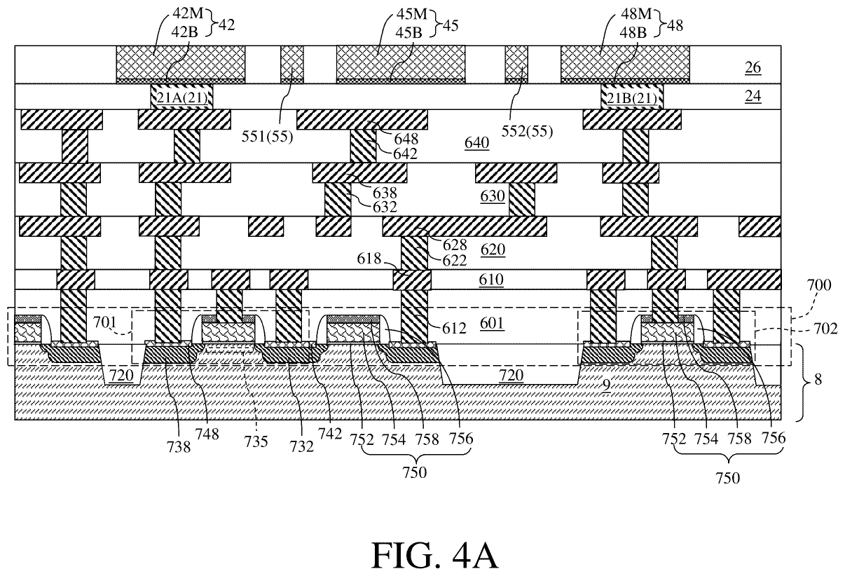

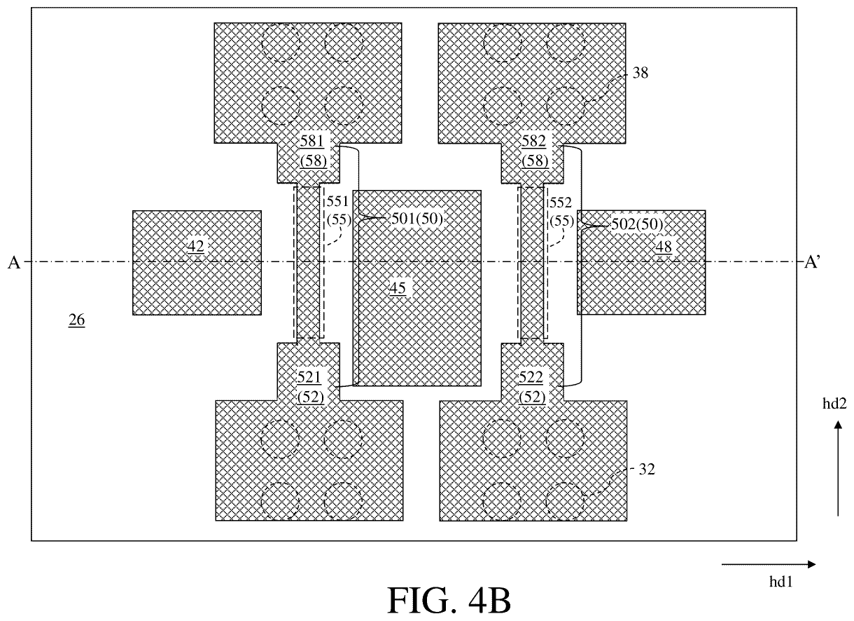

Referring to FIGS. 4A and 4B, a dielectric material may be deposited over the various patterned portions of the at least one metallic material layer 40L, which includes the heater elements 50, the first metallic plate 42, the second metallic plate 45, and the third metallic plate 48. The dielectric material comprises a planarizable dielectric material or a self-planarizing dielectric material. For example, the dielectric material may comprise undoped silicate glass having a dielectric constant of 3.9, a doped silicate glass having a dielectric constant in a range from 3.5 to 3.9, organosilicate glass having a dielectric constant in a range from 2.2 to 3.0, or nanoglass having a dielectric constant of about 1.3. Excess portions of the dielectric material may be removed from above the horizontal plane including the top surfaces of the heater elements 50, the first metallic plate 42, the second metallic plate 45, and the third metallic plate 48. Remaining portions of the dielectric material comprise a dielectric material layer, which is herein referred to as an electrode-level dielectric layer 26.

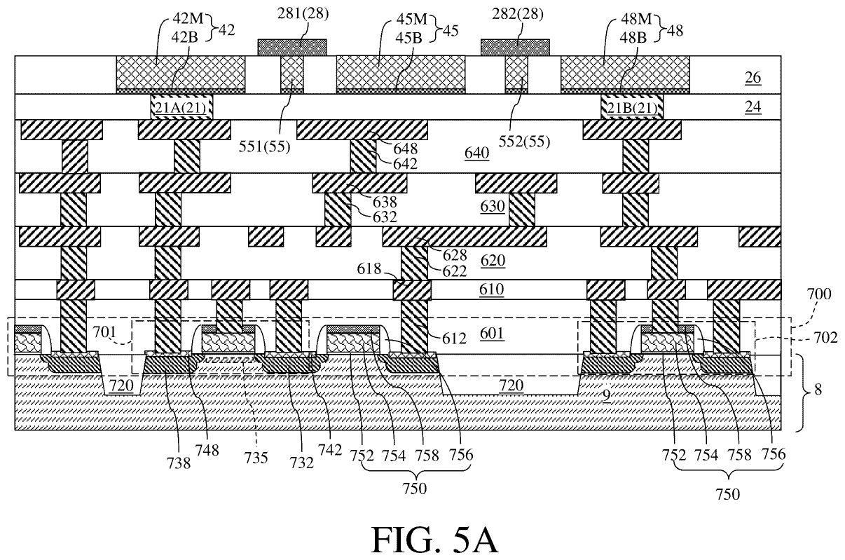

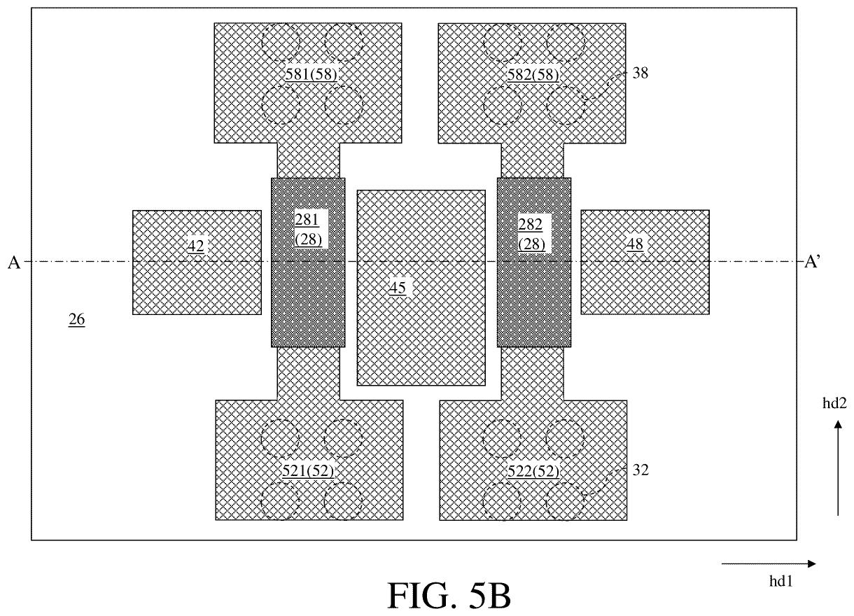

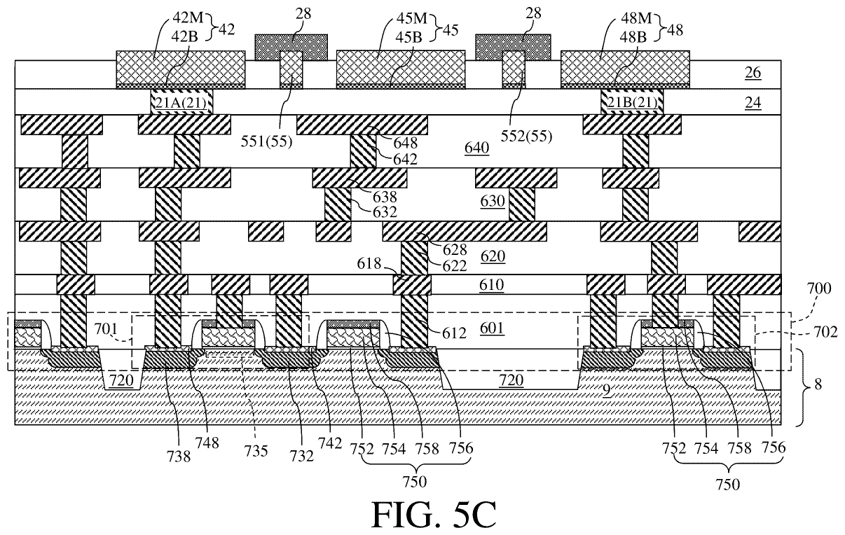

Referring to FIGS. 5A and 5B, a thermally-conductive layer may be formed over the electrode-level dielectric layer 26 and may be patterned into thermally-conductive plates 28. The thermally-conductive layer comprises a dielectric material that may provide a reasonably high thermal conductivity to facilitate heat dissipation from the heater elements 50. For example, the thermally-conductive layer may have thermal conductivity in a range from 1 W/m·K to 2,300 W/m·K. For example, the thermally-conductive layer may comprise aluminum nitride, tantalum nitride, silicon nitride, boron nitride, silicon carbide, silicon oxide, silicon oxycarbide, and diamond. Aluminum nitride has thermal conductivity in a range from 140 W/m·K to 180 W/m·K. Tantalum nitride has thermal conductivity in a range from 20 W/m·K to 30 W/m·K. Silicon nitride has thermal conductivity in a range from 10 W/m·K to 30 W/m·K. Boron nitride, in its hexagonal form, has a thermal conductivity of approximately 600 W/m·K. Silicon carbide has thermal conductivity in a range from 120 W/m·K to 270 W/m·K. Silicon oxide has a thermal conductivity of about 1.4 W/m·K. Diamond exhibits an exceptionally high thermal conductivity, ranging from 900 W/m·K to 2300 W/m·K. The thermally-conductive layer may be deposited by chemical vapor deposition and may have a thickness in a range from 6 nm to 60 nm, such as from 12 nm to 30 nm, although lesser and greater thicknesses may also be used.

A photoresist layer (not shown) may be applied over the thermally-conductive layer, and may be lithographically patterned to form patterns that cover the strip portions 55 of the heater elements 50. Predominant portions (i.e., more than 50%) of each of the first metallic plate 42, the second metallic plate 45, and the third metallic plate 48 are not covered by the patterned photoresist layer. An etch process may be performed to etch portions of the thermally-conductive layer that are not masked by the photoresist layer. The etch process etches the material of the thermally-conductive layer selective to the materials of the heater elements 50, the heater elements 50, the first metallic plate 42, the second metallic plate 45, and the third metallic plate 48. The etch process may comprise an anisotropic etch process (such as a reactive ion etch process) or an isotropic etch process (such as a wet etch process). The patterned portions of the thermally-conductive layer comprise the thermally-conductive plates 28. The photoresist layer may be subsequently removed, for example, by ashing. The thermally-conductive plates 28 may comprise a first thermally-conductive plate 281 that covers the first-heater strip portion 551, and a second thermally-conductive plate 282 that covers the second-heater strip portion 552.

Referring to FIG. 5C, a first alternative configuration of the embodiment structure may be derived from the embodiment structure of FIGS. 5A and 5B by vertically recessing the top surface of the electrode-level dielectric layer 26 prior to formation of the thermally conductive plates 28. In this case, an additional processing step may be performed before formation of the thermally conductive plates 28 to vertically recess the dielectric material of the electrode-level dielectric layer 26 selectively to the metallic materials of the first metallic plate 42, the second metallic plate 45, and the third metallic plate 48. In this embodiment, upper surface segments of sidewalls of the first metallic plate 42, the second metallic plate 45, and the third metallic plate 48 may be physically exposed upon recessing the electrode-level dielectric layer 26 selectively to the metallic materials of the first metallic plate 42, the second metallic plate 45, and the third metallic plate 48. The recess depth may be in a range from 1% to 90%, such as from 10% to 50%, of the thickness of the electrode-level dielectric layer 26. In this embodiment, the thermally conductive plates 28 may contact upper surface segments of sidewalls of the strip portions 55 of the heater elements 50.

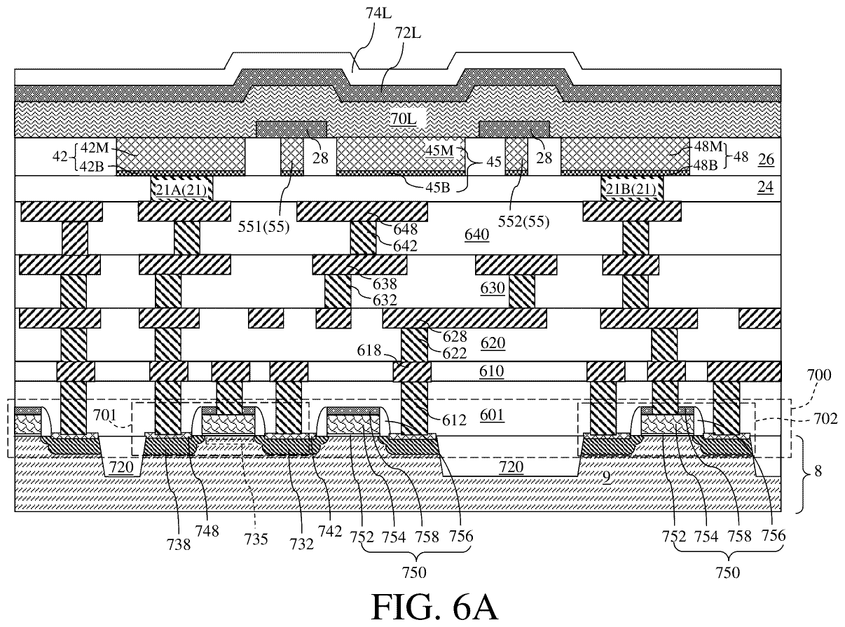

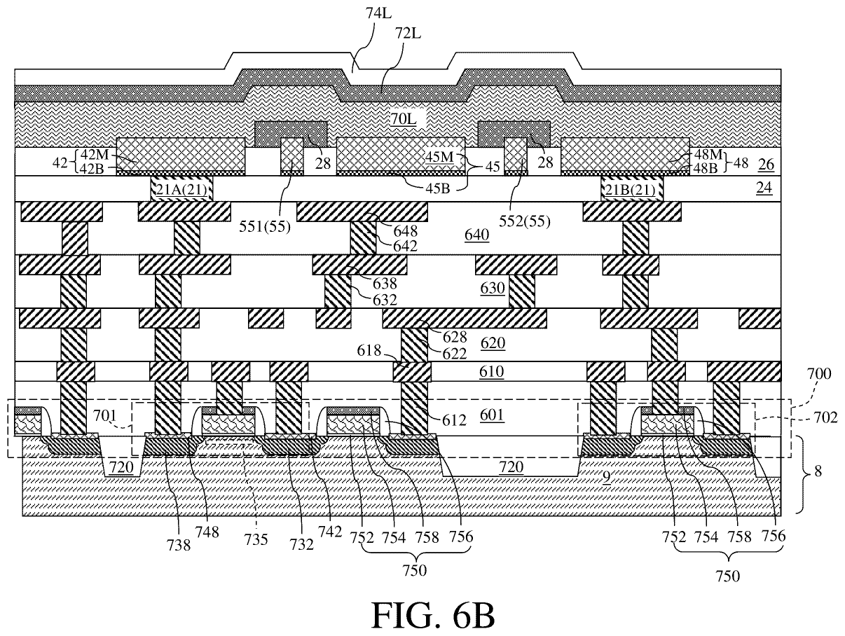

Referring to FIGS. 6A and 6B, a phase change material (PCM) layer 70L and at least one cover dielectric layer (72L, 74L) may be deposited over the thermally-conductive plates 28 and over the first electrode (comprising the first metallic plate 42), the first heater element 501 (shown in FIGS. 4A and 4B), the second electrode (comprising the second metallic plate 45), the third electrode (comprising the second metallic plate 45), the second heater element 502 (shown in FIGS. 4A and 4B), and the fourth electrode (comprising the third metallic plate 48). The phase change material layer 70L may be deposited directly on the physically exposed top surface portions of the first metallic plate 42, the second metallic plate 45, the third metallic plate 48, and the heater elements 50. FIG. 6A corresponds to the configuration that is derived from the configuration of the embodiment structure illustrated in FIGS. 5A and 5B. FIG. 6B corresponds to the first alternative configuration illustrated in FIG. 5C, in which the top surface of the electrode-level dielectric layer 26 is vertically recessed relative to the top surfaces of the first metallic plate 42, the second metallic plate 45, and the third metallic plate 48.

The phase change material layer 70L comprises, and/or consists essentially of, a phase change material. As used herein, a “phase change material” refers to a material having at least two different phases providing different resistivity. A phase change material (PCM) may be used to store information as a resistivity state of a material that may be in different resistivity states corresponding to different phases of the material. The different phases may include an amorphous state having high resistivity and a crystalline state having low resistivity (i.e., a lower resistivity than in the amorphous state). The transition between the amorphous state and the crystalline state may be induced by controlling the rate of cooling after application of an electrical pulse that renders the phase change material amorphous in a first part of a programming process. The second part of the programming process includes control of the cooling rate of the phase change material. In embodiments in which rapid quenching occurs, the phase change material may cool into an amorphous high resistivity state. In embodiments in which slow cooling occurs, the phase change material may cool into a crystalline low resistivity state.

Exemplary phase change materials include, but are not limited to, germanium antimony telluride (GST) compounds such as Ge₂Sb₂Te₅ or GeSb₂Te₄, germanium antimony compounds, indium germanium telluride compounds, aluminum selenium telluride compounds, indium selenium telluride compounds, and aluminum indium selenium telluride compounds. The phase change material may be doped (e.g., nitrogen doped GST) or undoped to enhance resistance-switching characteristics. The phase change material layer 70L may be deposited by physical vapor deposition. The thickness of the phase change material layer 70L may be in a range from 1 nm to 1,000 nm, such as from 30 nm to 300 nm, although lesser and greater thicknesses may also be used.

At least one cover dielectric layer (72L, 74L) may be deposited over the phase change material layer 70L. In one embodiment, the at least one cover dielectric layer (72L, 74L) may comprise a stack of a first cover dielectric layer 72L and a second cover dielectric layer 74L. In one embodiment, the first cover dielectric layer 72L may comprise a dielectric barrier material such as silicon nitride or silicon carbonitride, and the second cover dielectric layer 74L may comprise a dielectric material that is different from the dielectric barrier material. For example, the second cover dielectric layer 74L may comprise silicon oxide. The first cover dielectric layer 72L and the second cover dielectric layer 74L may be deposited by a respective chemical vapor deposition. The thickness of the first cover dielectric layer 72L may be in a range from 10 nm to 100 nm, such as from 20 nm to 60 nm, although lesser and greater thicknesses may also be used. The thickness of the second cover dielectric layer 74L may be in a range from 10 nm to 100 nm, such as from 20 nm to 60 nm, although lesser and greater thicknesses may also be used.

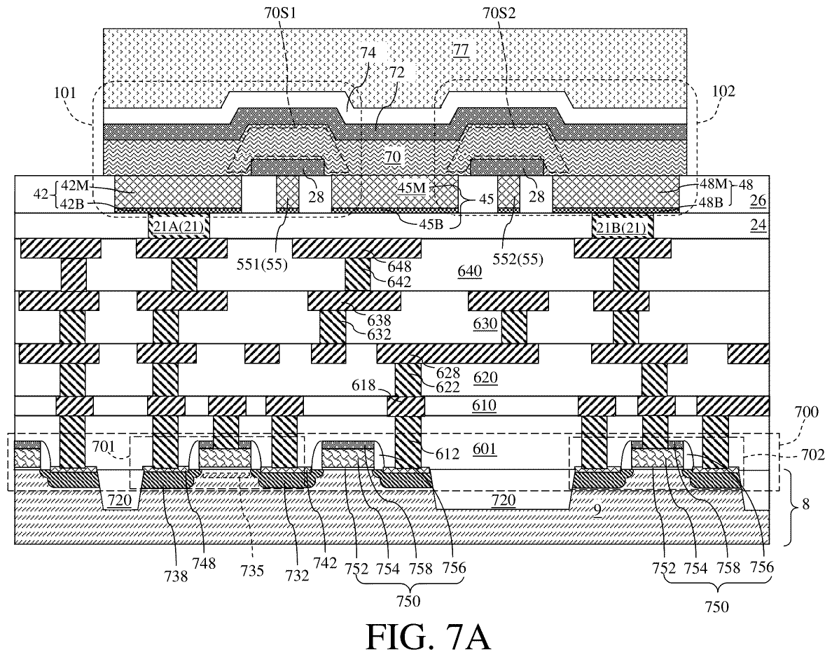

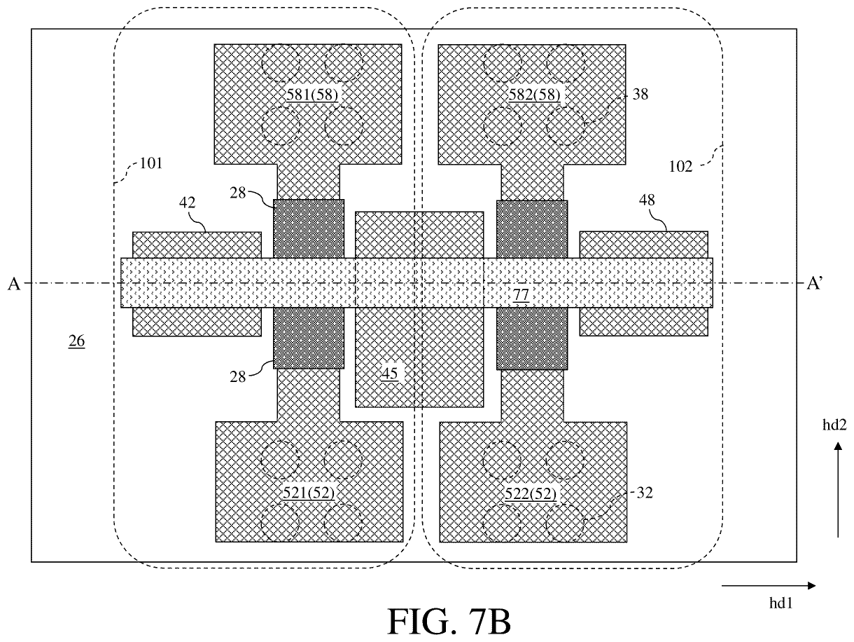

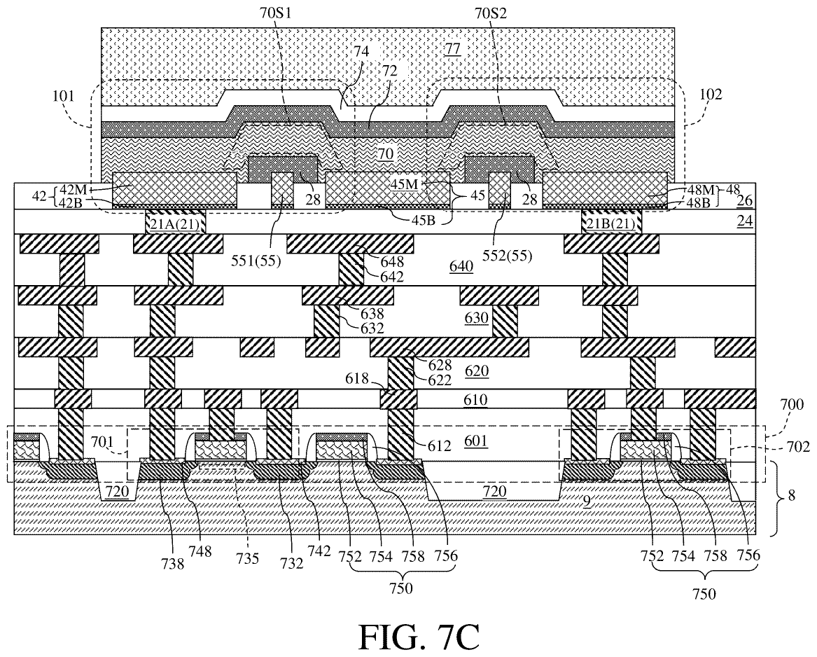

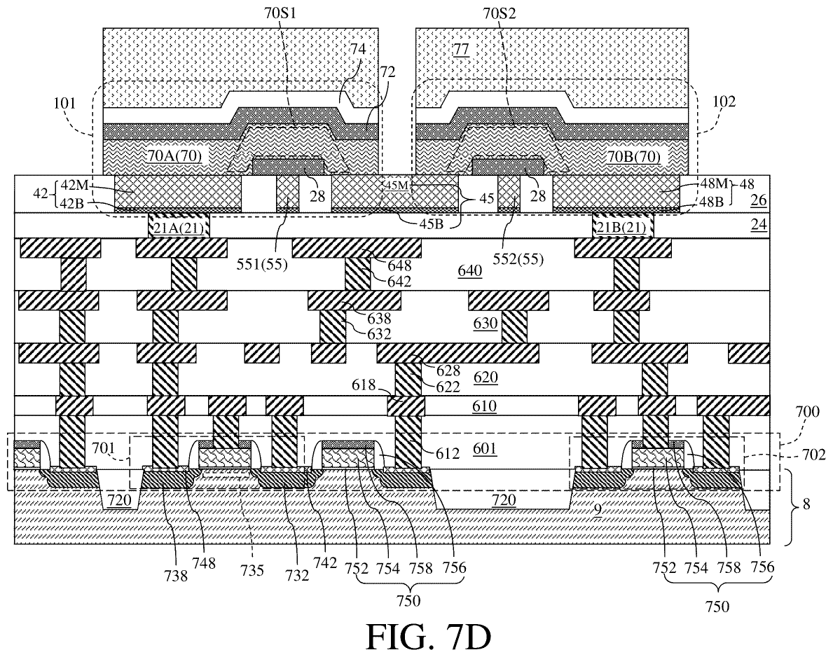

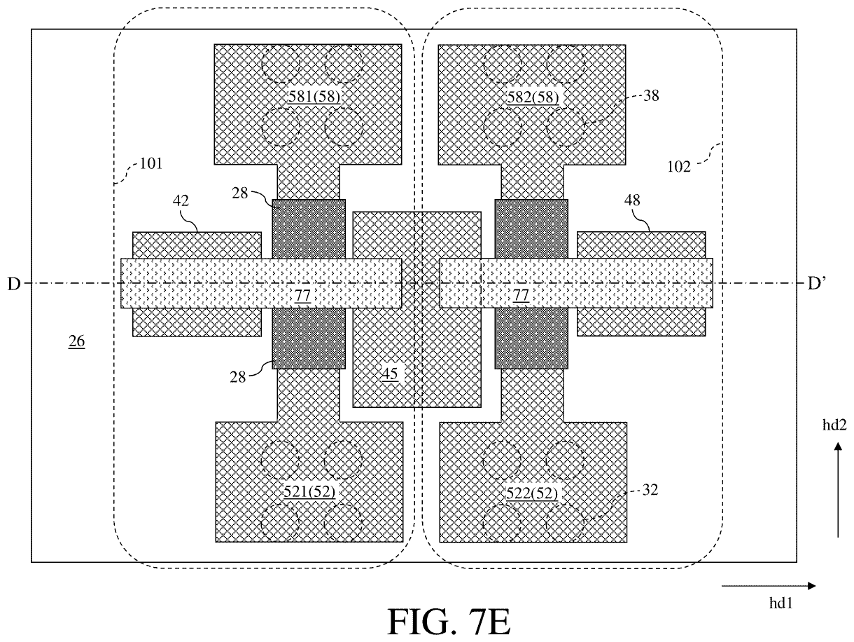

Referring to FIGS. 7A-7E, a patterned etch mask portion 77 may be formed over the at least one cover dielectric layer (72L, 74L). FIGS. 7A and 7B illustrate a configuration that is derived from the embodiment structure illustrated in FIG. 6A. FIG. 7C illustrates a first alternative configuration that is derived from the first alternative configuration of the embodiment structure illustrated in FIG. 6B. FIGS. 7D and 7E illustrate a second alternative configuration of the embodiment structure that may be derived from the embodiment structure illustrated in FIG. 6A or from the first alternative configuration of the embodiment structure illustrated in FIG. 6B. In the configuration illustrated in FIGS. 7A and 7B, the top surface of the electrode-level dielectric layer 26 is located within the same horizontal plane as the top surfaces of the first metallic plate 42, the second metallic plate 45, and the third metallic plate 48, and the phase change material layer 70L is patterned into a single continuous phase change material portion 70. In the configuration illustrated in FIG. 7C, the top surface of the electrode-level dielectric layer 26 is vertically recessed relative to the top surfaces of the first metallic plate 42, the second metallic plate 45, and the third metallic plate 48, and the phase change material layer 70L is patterned into a single continuous phase change material portion 70. In the configuration illustrated in FIGS. 7D and 7E, the top surface of the electrode-level dielectric layer 26 may be, or may not be, vertically recessed relative to the top surfaces of the first metallic plate 42, the second metallic plate 45, and the third metallic plate 48, and the phase change material layer 70L is patterned into a plurality of phase change material portion 70.

For example, a photoresist layer may be applied over the at least one cover dielectric layer (72L, 74L), and may be lithographically patterned to provide an elongated photoresist material portion that functions as the patterned etch mask portion 77. The patterned etch mask portion 77 straddles the strip portions 55 of the two heater elements 50 and the second metallic plate 45 along the first horizontal direction hd1. In some embodiments, the patterned etch mask portion 77 may straddle the first metallic plate 42 and the third metallic plate 48. In one embodiment, the patterned etch mask portion 77 may have a rectangular horizontal cross-sectional shape having lengthwise edges that are parallel to the first horizontal direction hd1 and having widthwise edges that are parallel to the second horizontal direction hd2.

Unmasked portions of at least one cover dielectric layer (72L, 74L) and the phase change material layer 70L may be etched by performing an anisotropic etch process that uses the patterned etch mask portion 77 as an etch mask. Thus, the anisotropic etch process etches portions of the at least one cover dielectric layer (72L, 74L) and the phase change material layer 70L that are not masked by the patterned etch mask portion 77. A remaining portion of the at least one cover dielectric layer (72L, 74L) comprises at least one cover dielectric plate (72, 74). In one embodiment, the at least one cover dielectric plate (72, 74) may comprise a stack of a first cover dielectric plate 72 and a second cover dielectric plate 74. The first cover dielectric plate 72 may comprise a patterned portion of the first cover dielectric layer 72L, and the second cover dielectric plate 74 may comprise a patterned portion of the second cover dielectric layer 74L.

The phase change material layer 70L may be patterned into at least one phase change material portion. Generally, the at least one phase change material portion may comprise a single phase change material portion 70 as illustrated in FIGS. 7A and 7B or in FIG. 7C, or may comprise a plurality of phase change material portion 70 as illustrated in FIGS. 7D and 7R. The at least one phase change material portion comprises a first patterned portion that extends over the first metallic plate 42, the first heater element 501 (shown in FIGS. 4A and 4B), and a first portion of the second metallic plate 45, and a second patterned portion that extends over a second portion of the second metallic plate 45, the second heater element 502 (shown in FIGS. 4A and 4B), and the third metallic plate 48. The first patterned portion of the phase change material layer 70L comprises a first phase change region 70S1 that may be programmed into an amorphous phase or into a crystalline phase and overlies the first-heater strip portion 551. The second patterned portion of the phase change material layer 70L comprises a second phase change region 70S2 that may be programmed into an amorphous phase or into a crystalline phase and overlies the second-heater strip portion 552. Thus, the first patterned portion of the phase change material extends over the first electrode (comprising a first metallic plate 42), the first heater element 501, and the second electrode (comprising a second metallic plate 45), and the second patterned portion of the phase change material extends over the third electrode (comprising the second metallic plate 45), the second heater element 502, and the fourth electrode (comprising a third metallic plate 48).

The first patterned portion of the phase change material layer 70L may be disjoined from, or may be adjoined to, the second patterned portion of the phase change material layer 70L. In the configurations illustrated in FIGS. 7A and 7B and in the first alternative configuration illustrated in FIG. 7C, the first patterned portion of the phase change material layer 70L is adjoined to the second patterned portion of the phase change material layer 70L. In such configurations, the first patterned portion of and the second patterned portion may be formed as a respective portion of a single continuous phase change material portion 70 that extends over each of the first heater element 501 and the second heater element 502. In one embodiment, the single continuous phase change material portion 70 laterally extends along a first horizontal direction hd1 with a uniform width along a second horizontal direction hd2, and contacts top surfaces of the first electrode (comprising a first metallic plate 42), the second electrode (comprising a second metallic plate 45), the third electrode (comprising the second metallic plate 45), and the fourth electrode (comprising a third metallic plate 48). In this embodiment, the at least one cover dielectric plate (72, 74) and the phase change material portion 70 straddle the strip portions 55 of the heater elements 50 and the second metallic plate 45 (which comprise the second electrode of a first (PCM) switch 101 and the third electrode of a second (PCM) switch 102). The phase change material portion 70 contacts, and extends over, the second metallic plate 45 and at least portions of the first metallic plate 42 and the third metallic plate 48 that are proximal to the strip portions 55 of the heater elements 50.

In the second alternative configuration illustrated in FIGS. 7D and 7E, the first patterned portion of the phase change material layer 70L is disjoined from the second patterned portion of the phase change material layer 70L. Thus, a first phase change material portion 70A may extend over the first electrode (comprising a first metallic plate 42), the first heater element 501, and the second electrode (comprising a second metallic plate 45), and a first phase change material portion 70B may extends over the third electrode (comprising the second metallic plate 45), the second heater element 502, and the fourth electrode (comprising a third metallic plate 48). The lateral distance between the first phase change material portion 70A and the second phase change material portion 70B may be in a range from 0.1 micron to 100 microns, although lesser and greater lateral distances may also be used.

The patterned etch mask portion 77 may be subsequently removed, for example, by ashing. A first phase change material (PCM) switch 101 and a second PCM switch 102 may be formed over the first dielectric material layers (601, 610, 620, 630, 640, 24). The first PCM switch 101 comprises a first electrode (which may comprise a first metallic plate 42) and a second electrode (which may comprise a second metallic plate 45), and the second PCM switch 102 comprises a third electrode (which may comprise the second metallic plate 45) and a fourth electrode (which may comprise a third metallic plate 48). In one embodiment, the second electrode (which may comprise a second metallic plate 45) is electrically connected to the third electrode (which may comprise the second metallic plate 45) to form a common electrical node. In one embodiment, the second metallic plate 45 is a common electrode of the first PCM switch 101 and the second PCM switch 102.

The first PCM switch 101 comprises a first heater element 501 located between the first electrode (comprising a first metallic plate 42) and the second electrode (comprising a second metallic plate 45). The second PCM switch 102 comprises a second heater element 502 located between the third electrode (comprising the second metallic plate 45) and the fourth electrode (comprising a third metallic plate 48). Each of the first heater element 501 and the second heater element 502 comprises a same set of at least one metallic material as the first metallic plate 42, the second metallic plate 45, and the third metallic plate 48.

In one embodiment, the second electrode (comprising a second metallic plate 45) and the third electrode (comprising the second metallic plate 45) are formed as a single metallic plate (such as the second metallic plate 45). In one embodiment, a first subset of the first metal interconnect structures (612, 618, 622, 628, 632, 638, 642, 648, 21A) provides a first electrically conductive path between the first electrode (comprising a first metallic plate 42) and an output node of the power amplifier 701, and a second subset of the first metal interconnect structures (612, 618, 622, 628, 632, 638, 642, 648, 21B) provides a second electrically conductive path between the fourth electrode (comprising a third metallic plate 48) and an input node of the power amplifier 701.

According to an aspect of the present disclosure, the two PCM RF switching system provides high signal-to-ratio switching for the power amplifier 701 and the low noise amplifier 702. As such, shunt transistors are not necessary for operation of the two PCM RF switching system of the present disclosure. In one embodiment, the output node of the power amplifier 701 is the only electrical node of the semiconductor circuit 700 to which the first electrode (comprising a first metallic plate 42) is electrically connected, and the input node of the low noise amplifier 702 is the only electrical node of the semiconductor circuit 700 to which the fourth electrode (comprising a third metallic plate 48) is electrically connected.

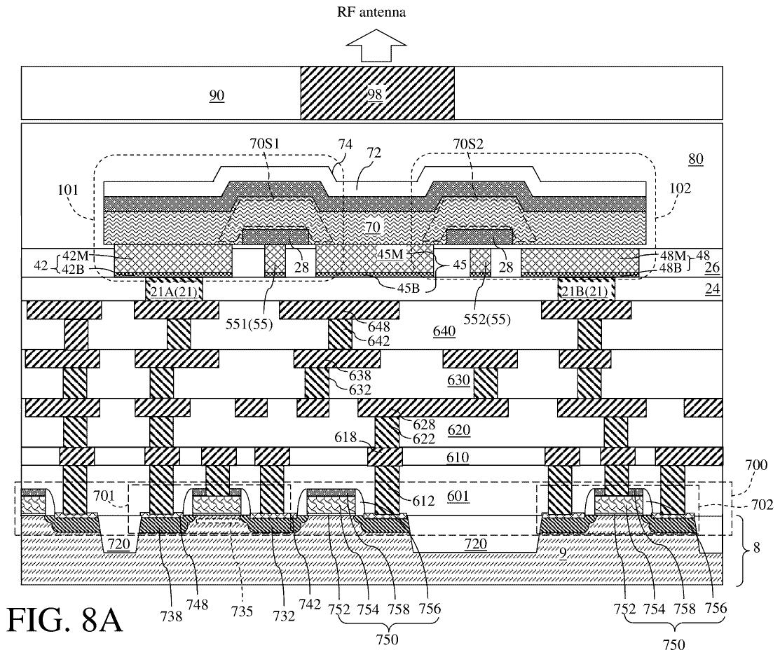

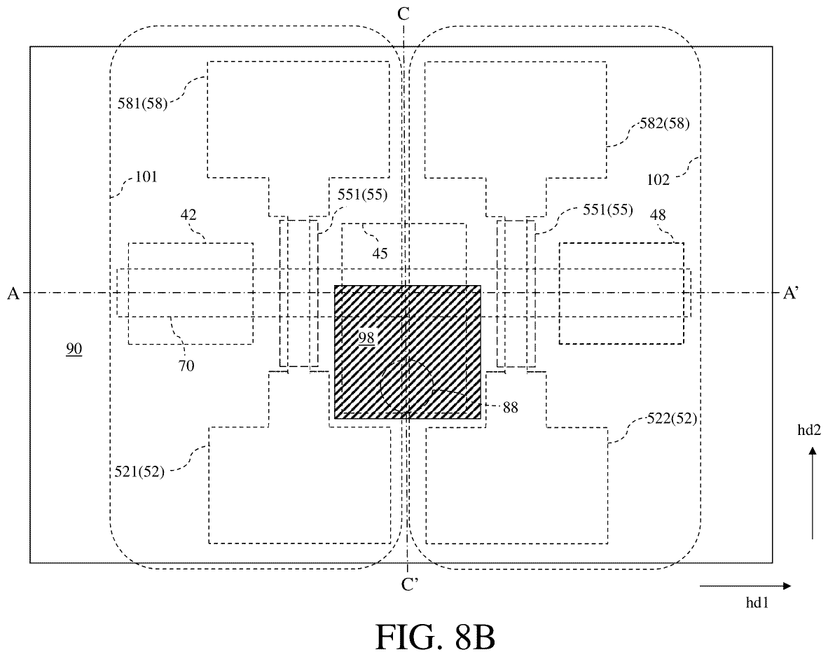

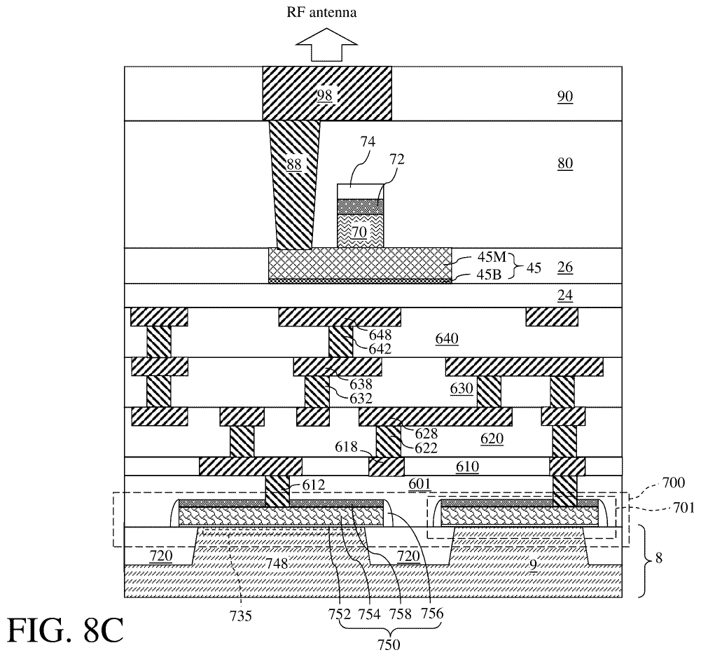

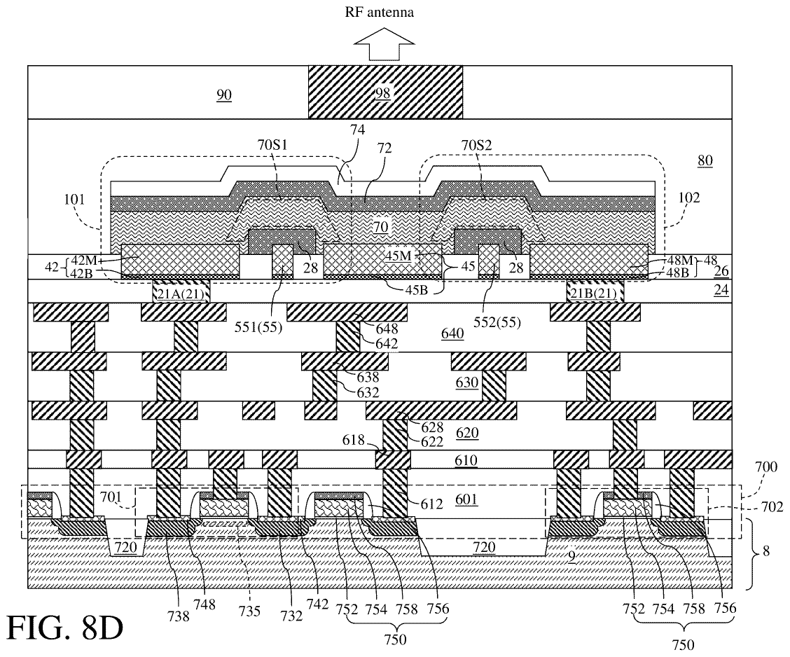

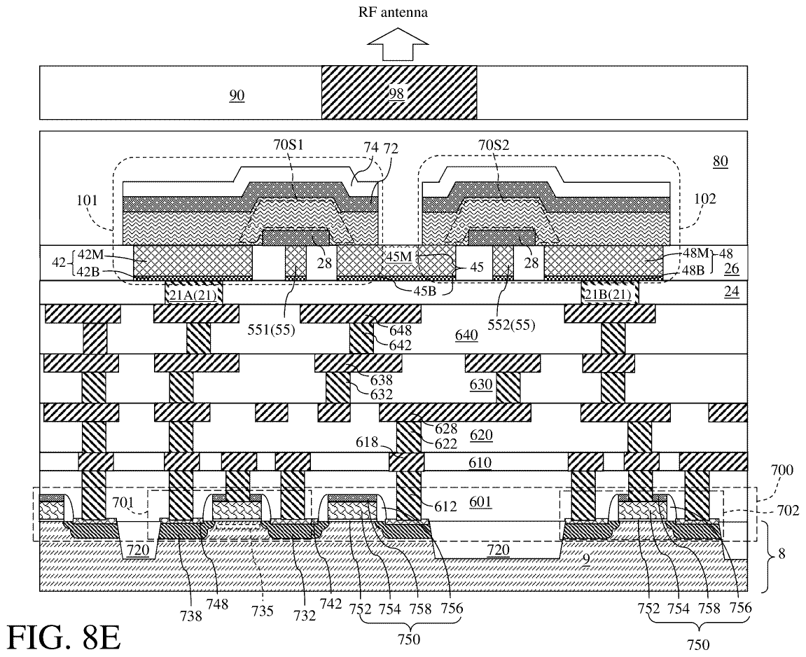

Referring to FIGS. 8A-8E, a PCM-level dielectric material layer 80 may be deposited over the first PCM switch 101 and the second PCM switch 102. FIGS. 8A-8C illustrate a configuration of the embodiment structure that can be derived from the configuration illustrated in FIGS. 7A and 7B. FIG. 8D illustrates a first alternative configuration of the embodiment structure that can be derived from the configuration illustrated in FIG. 7C. FIG. 8E illustrates a second alternative configuration of the embodiment structure that may be derived from the configuration illustrated in FIGS. 7D and 7E. The PCM-level dielectric material layer 80 comprises an interlayer dielectric (ILD) material such as undoped silicate glass, a doped silicate glass, porous or non-porous organosilicate glass, etc. The thickness of the PCM-level dielectric material layer 80 may be in a range from 200 nm to 1,200 nm, although lesser and greater thicknesses may also be used. The PCM-level dielectric material layer 80 is a bottommost layer among second dielectric material layers that are formed over the first PCM switch 101 and the second PCM switch 102.

According to an aspect of the present disclosure, a metallic via structure 88 may be formed through the PCM-level dielectric material layer 80 directly on a top surface of the second metallic plate 45, which constitutes a combination of the second electrode of the first PCM switch 101 and the third electrode of the second PCM switch 102.

Subsequently, additional second dielectric material layers may be formed over the PCM-level dielectric material layer 80. The additional second dielectric material layers may comprise, for example, a line-level dielectric layer 90. A metal line structure 98 may be formed directly on a top surface of the metallic via structure 88 in the line-level dielectric layer 90.

Generally, second dielectric material layers (80, 90) may be formed over the first PCM switch 101 and the second PCM switch 102, and a metallic via structure 88 may be formed through a bottommost layer among the second dielectric material layers (80, 90) directly on a top surface of a single metallic plate (such as the second metallic plate 45) that forms the second electrode of the first PCM switch 101 and the third electrode of the second PCM switch 102.

A radio-frequency (RF) antenna may be electrically connected to the second metallic plate 45 through the metallic via structure 88 and the metal line structure 98 by forming the RF antenna over the second dielectric material layers (80, 90) or by attaching a structure (such an integrated passive device (IPD) die or an additional semiconductor die) including the RF antenna to an assembly containing the substrate 8, the first dielectric material layers (601, 610, 620, 630, 640, 24), and the second dielectric material layers (80, 90).

The RF antenna may have any configuration known in the art. Examples of such configurations include microstrip antennas, planar inverted-F antennas (PIFA), spiral antennas, dipole antennas, and slot antennas. Each of these configurations exhibits distinct structural features suited for various applications. Microstrip antennas typically comprise a flat conductive strip (patch) positioned on top of a dielectric substrate with a ground plane on the opposite side, generally appearing as a rectangular or circular patch of metal, and are frequently utilized in wireless communication devices due to their simplicity and ease of integration. Planar inverted-F antennas (PIFA), a variant of the microstrip antenna, incorporate a shorting pin connecting the patch to the ground plane, appearing as a rectangular patch with a reduced dimension relative to its width and a shorting pin, making them prevalent in mobile phones and compact devices. Spiral antennas comprise a spiral-shaped conductor, manifesting as a circular or rectangular spiral pattern, and are used for wideband applications due to their extensive frequency response. Dipole antennas comprise two conductive elements (arms) aligned in a straight line, appearing as two straight metal lines extending from a central feed point, and are commonly used in fundamental RF applications. Slot antennas are manufactured by cutting a slot in a conductive plane, appearing as a rectangular or other shaped slot in a metallic surface, and are appropriate for integration with planar structures. These antenna configurations may be integrated into semiconductor dies utilizing advanced fabrication techniques to ensure precision and performance, thereby enhancing the functionality and efficiency of RF communication systems in various applications.

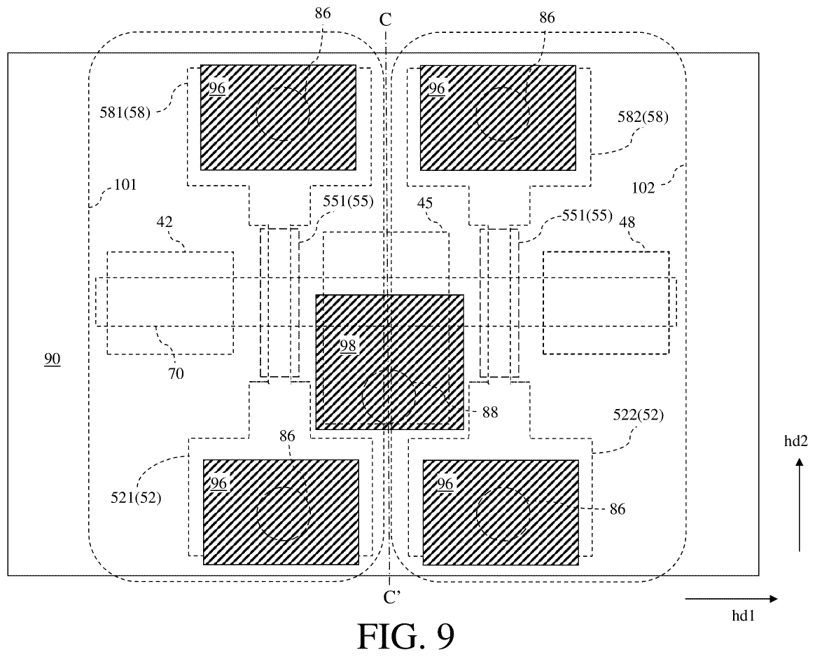

Referring to FIG. 9, a top-down view of an alternative configuration of the embodiment structure is illustrated. The alternative configuration may be derived from the embodiment structure of FIGS. 8A-8E by providing electrical contacts to the first-heater first terminal portion 521, the first-heater second terminal portion 581, the second-heater first terminal portion 522, and the second-heater second terminal portion 582 using additional metal via structures 86 vertically extending through the PCM-level dielectric material layer 80 and additional metal line structures 96 formed within the line-level dielectric layer 90.

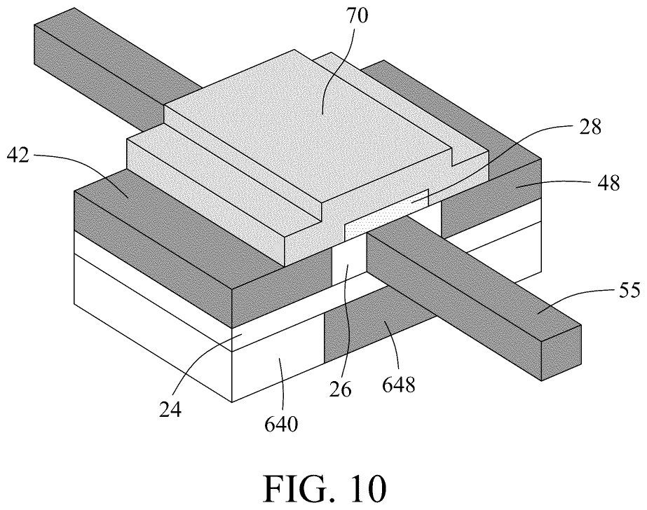

Referring to FIG. 10, a perspective view of a portion of an exemplary configuration of a PCM switch is illustrated. It is understood that the lateral extents of the phase change material portion 70 may be varied according to the various alternative configurations described above.

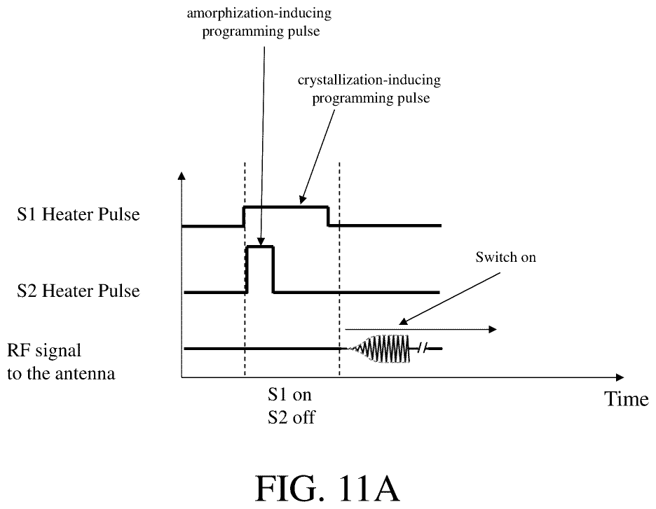

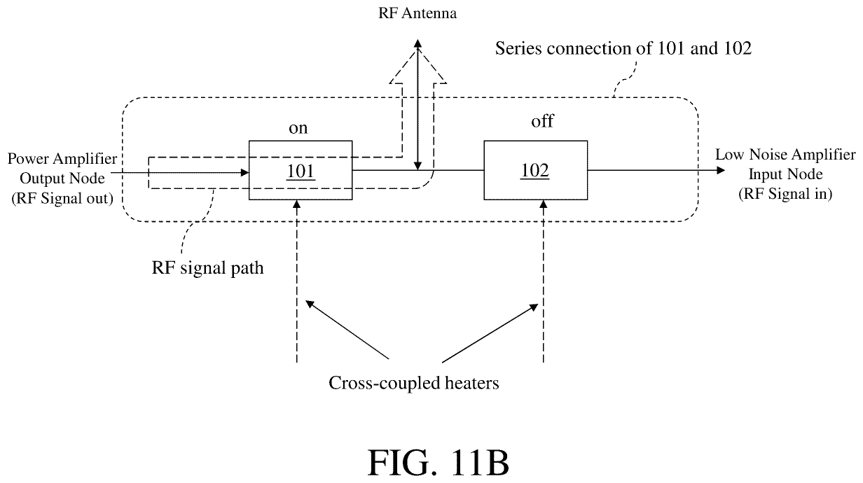

Referring to FIG. 11A, a timing diagram is illustrated for heater pulse signals and an RF transmission output signal during transition into a first operational state of a phase change material (PCM) switching circuit. In order to turn on the first PCM switch 101 and to turn off the second PCM switch 102, a crystallization-inducing programming pulse may be applied across the first-heater strip portion 551 (shown in FIGS. 4A and 4B) of the first PCM switch 101 as a first switch heater pulse (S1 heater pulse), and an amorphization-inducing programming pulse may be applied across the second-heater strip portion 552 (shown in FIGS. 4A and 4B) of the second PCM switch 102 as a second switch heater pulse (S2 heater pulse). The first PCM switch 101 is turned on, and the second PCM switch 102 is turned off. A radio-frequency signal from the output node of the power amplifier 701 may be supplied to the RF antenna once the first PCM switch is turned on.

FIG. 11B schematically illustrates the signal path from the output node of the power amplifier 701 to the RF antenna while the first PCM switch 101 is turned on and the second PCM switch 102 is turned off. The PCM RF switching system of the present disclosure may be configured as a single pull double through switch that turns on only one of the switches at any time.

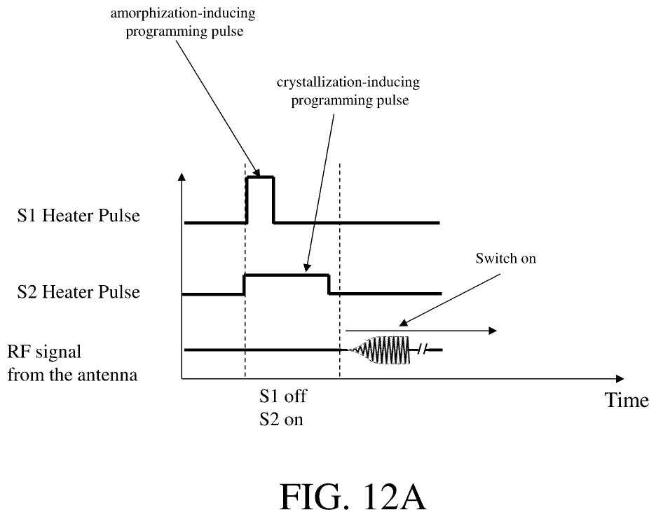

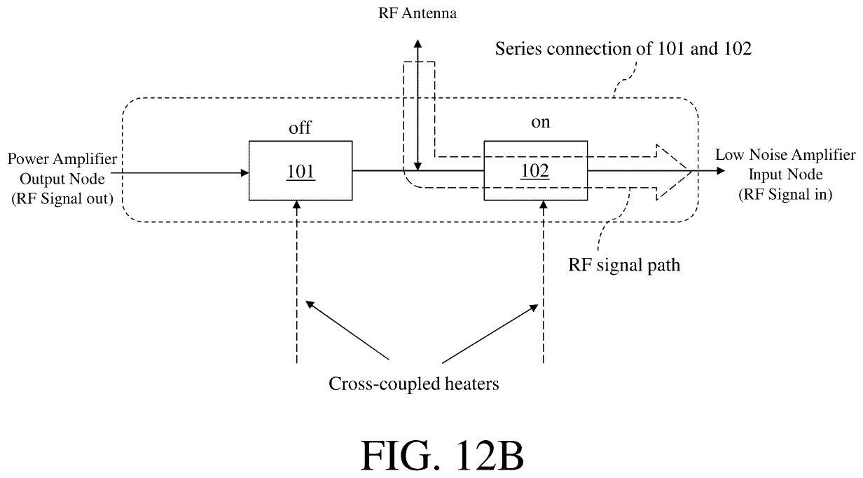

Referring to FIG. 12A, a timing diagram is illustrated for heater pulse signals and an RF transmission input signal during transition into a second operational state of the phase change material (PCM) switching circuit. In order to turn off the first PCM switch 101 and to turn on the second PCM switch 102, an amorphization-inducing programming pulse may be applied across the first-heater strip portion 551 (shown in FIGS. 4A and 4B) of the first PCM switch 101 as a first switch heater pulse (S1 heater pulse), and a crystallization-inducing programming pulse may be applied across the second-heater strip portion 552 (shown in FIGS. 4A and 4B) of the second PCM switch 102 as a second switch heater pulse (S2 heater pulse). The first PCM switch 101 is turned off, and the second PCM switch 102 is turned on. A radio-frequency signal to the input node of the power amplifier 701 may be supplied from the RF antenna once the second PCM switch is turned on.

FIG. 12B schematically illustrates the signal path from the RF antenna to the input node of the low noise amplifier 702 while the first PCM switch 101 is turned off and the second PCM switch 102 is turned on.

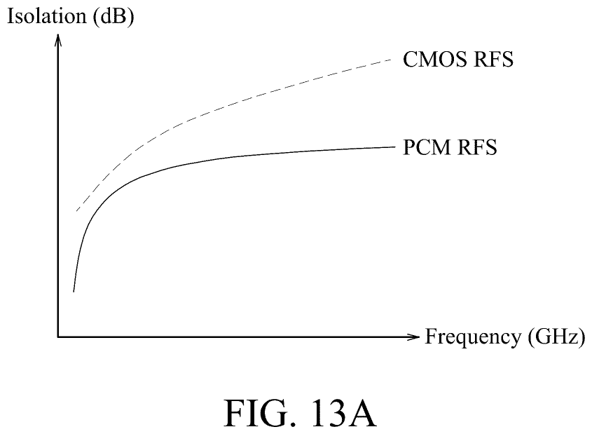

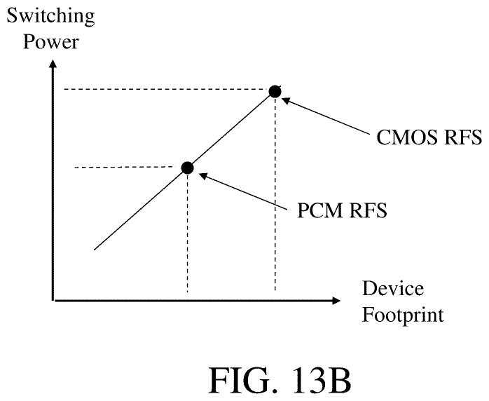

Referring to FIG. 13A, a diagram illustrates the noise level in the input node of a low noise amplifier 702 that is connected to the PCM switching circuit of the present disclosure, and the noise level at the input node of a low noise amplifier connected to a conventional CMOS switching circuit using conventional CMOS transistors as signal switches and having a comparable device footprint (i.e., about the same device area on a semiconductor substrate). The PCM switching circuit of the present disclosure may provide superior signal isolation compared to the conventional CMOS switching circuit.

Referring to FIG. 13B, a diagram compares the device footprint and the switching power between a PCM switching circuit of the present disclosure and a related CMOS switching circuit using related CMOS transistors as signal switches and having a comparable device footprint. The various embodiment PCM switching circuit disclosed herein use less switching power (i.e., power consumption in the device) and less device footprint.

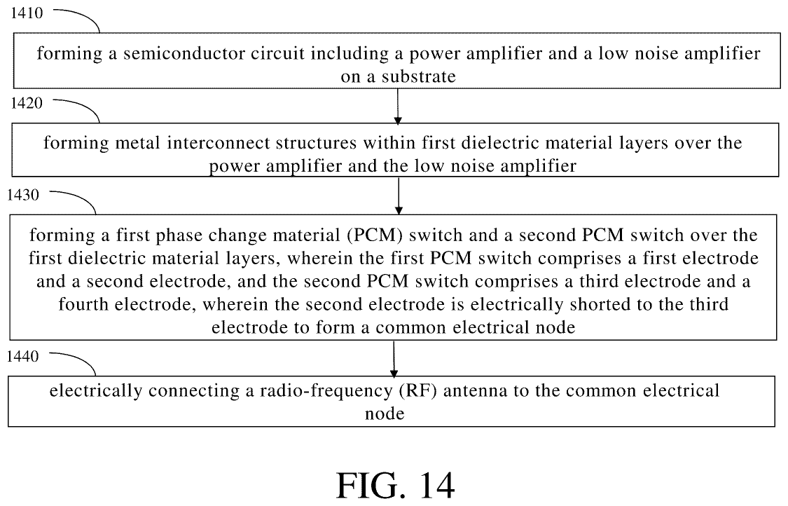

FIG. 14 is a first flowchart that illustrates general processing steps for manufacturing a device structure according to embodiments of the present disclosure.

Referring to step 1410 and FIGS. 1A and 1B, a semiconductor circuit 700 including a power amplifier 701 and a low noise amplifier 702 may be formed on a substrate 8.

Referring to step 1420 and FIGS. 1A and 1B, first metal interconnect structures (612, 618, 622, 628, 632, 638, 642, 648, 21, 32, 38) may be formed within first dielectric material layers (601, 610, 620, 630, 640, 24) may be formed over the power amplifier 701 and the low noise amplifier 702.

Referring to step 1430 and FIGS. 2-7B, a first phase change material (PCM) switch 101 and a second PCM switch 102 may be formed over the first dielectric material layers (601, 610, 620, 630, 640, 24). The first PCM switch 101 comprises a first electrode (comprising a first metallic plate 42) and a second electrode (comprising a second metallic plate 45), and the second PCM switch 102 comprises a third electrode (comprising the second metallic plate 45) and a fourth electrode (comprising a third metallic plate 48). The second electrode (comprising a second metallic plate 45) is electrically connected to the third electrode (comprising the second metallic plate 45) to form a common electrical node.

Referring to step 1440 and FIGS. 8A-9, a radio-frequency (RF) antenna may be electrically connected to the common electrical node.

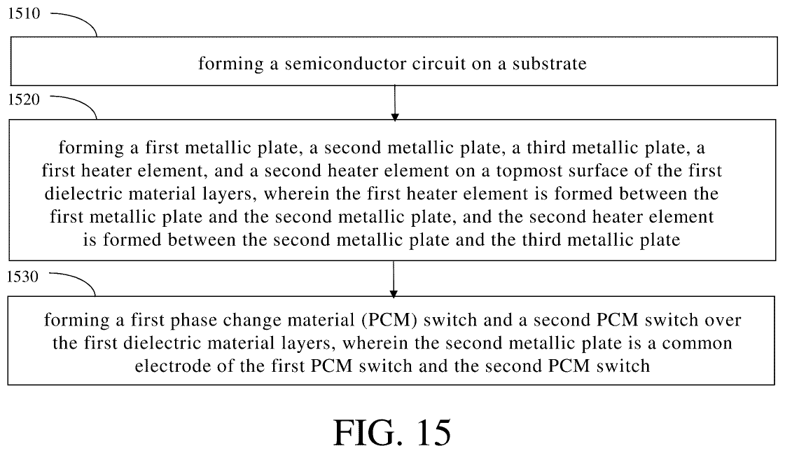

FIG. 15 is a second flowchart that illustrates general processing steps for manufacturing a device structure according to embodiments of the present disclosure.

Referring to step 1510 and FIGS. 1A and 1B, a semiconductor circuit 700 may be formed on a substrate 8. The semiconductor circuit 700 may include a power amplifier 701 and a low noise amplifier 702.

Referring to step 1520 and FIGS. 2-4B, a first metallic plate 42, a second metallic plate 45, a third metallic plate 48, a first heater element 501, and a second heater element 502 may be formed on a topmost surface of the first dielectric material layers (601, 610, 620, 630, 640, 24). The first heater element 501 is formed between the first metallic plate 42 and the second metallic plate 45, and the second heater element 502 is formed between the second metallic plate 45 and the third metallic plate 48. The first metallic plate 42 may be electrically connected to an output node of the power amplifier 701 and the third metallic plate 48 may be electrically connected to an input node of the low noise amplifier 702.

Referring to step 1530 and FIGS. 5A-9, a first phase change material (PCM) switch 101 and a second PCM switch 102 may be formed over the first dielectric material layers (601, 610, 620, 630, 640, 24). The second metallic plate 45 is a common electrode of the first PCM switch 101 and the second PCM switch 102.

Referring to all drawings and according to various embodiments of the present disclosure, a device structure comprises: a semiconductor circuit 700 including a power amplifier 701 and a low noise amplifier 702 located on a substrate 8; first metal interconnect structures (612, 618, 622, 628, 632, 638, 642, 648, 21, 32, 38) embedded in first dielectric material layers (601, 610, 620, 630, 640, 24) overlying the power amplifier 701 and the low noise amplifier 702; a first phase change material (PCM) switch 101 and a second PCM switch 102 located over the first dielectric material layers (601, 610, 620, 630, 640, 24), wherein the first PCM switch 101 comprises a first electrode (comprising a first metallic plate 42) and a second electrode (comprising a second metallic plate 45), and the second PCM switch 102 comprises a third electrode (comprising the second metallic plate 45) and a fourth electrode (comprising a third metallic plate 48), wherein the second electrode (comprising a second metallic plate 45) is electrically connected to the third electrode (comprising the second metallic plate 45) to provide a common electrical node; and a radio-frequency (RF) antenna electrically connected to the common electrical node.

In one embodiment, the first PCM switch 101 comprises a first heater element 501 located between the first electrode (comprising a first metallic plate 42) and the second electrode (comprising a second metallic plate 45); the second PCM switch 102 comprises a second heater element 502 located between the third electrode (comprising the second metallic plate 45) and the fourth electrode (comprising a third metallic plate 48); and each of the first heater element 501 and the second heater element 502 comprises a same set of at least one metallic material as the first electrode (comprising a first metallic plate 42).

In one embodiment, the first PCM switch 101 comprises a first phase change material portion; the second PCM switch 102 comprises a second phase change material portion; and the first phase change material portion and the second phase change material portion are respective portions of a single continuous phase change material portion 70 that extends over each of the first heater element 501 and the second heater element 502.

In one embodiment, the single continuous phase change material portion 70 laterally extends along a first horizontal direction hd1 with a uniform width along a second horizontal direction hd2, and contacts top surfaces of the first electrode (comprising a first metallic plate 42), the second electrode (comprising a second metallic plate 45), the third electrode (comprising the second metallic plate 45), and the fourth electrode (comprising a third metallic plate 48).

In one embodiment, the second electrode (comprising a second metallic plate 45) and the third electrode (comprising the second metallic plate 45) are formed as a single metallic plate (such as the second metallic plate 45).

In one embodiment, the device structure further comprises: second dielectric material layers (80, 90) over the first PCM switch 101 and the second PCM switch 102; and a metallic via structure vertically extending through a bottommost layer among the second dielectric material layers (80, 90) and contacting a top surface of the single metallic plate (such as the second metallic plate 45), wherein the RF antenna is electrically connected to the metallic plate through the metallic via structure.

In one embodiment, a first subset of the first metal interconnect structures (612, 618, 622, 628, 632, 638, 642, 648, 21, 32, 38) provides a first electrically conductive path between the first electrode (comprising a first metallic plate 42) and an output node of the power amplifier 701; a second subset of the first metal interconnect structures (612, 618, 622, 628, 632, 638, 642, 648, 21, 32, 38) provides a second electrically conductive path between the fourth electrode (comprising a third metallic plate 48) and an input node of the power amplifier 701; the output node of the power amplifier 701 is the only electrical node of the semiconductor circuit 700 to which the first electrode (comprising a first metallic plate 42) is electrically connected; and the input node of the low noise amplifier 702 is the only electrical node of the semiconductor circuit 700 to which the fourth electrode (comprising a third metallic plate 48) is electrically connected.

The various embodiments of the present disclosure may provide an advancement over traditional single pull double throw (SPDT) switches used in RF signal switching. By leveraging the unique properties of PCM materials, the disclosed SPDT PCM switch offers superior isolation and low power consumption while simplifying the overall design by eliminating shunt-cells. This feature not only reduces parasitic capacitance but also minimizes the device footprint, making it highly suitable for applications requiring compact and efficient RF signal switching. The inherent advantages of the PCM material, such as the ability to switch between high resistance and low resistance states with precise control, further enhance the performance and reliability of the SPDT PCM switch. As such, the various embodiments disclosed herein present a robust solution for next-generation RF switching applications, delivering improved isolation, reduced power consumption, and a simplified circuit design, ultimately contributing to the advancement of semiconductor technology.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming a semiconductor circuit including a power amplifier and a low noise amplifier on a substrate;
forming metal interconnect structures within first dielectric material layers over the power amplifier and the low noise amplifier;
forming a first phase change material (PCM) switch and a second PCM switch over the first dielectric material layers, wherein the first PCM switch comprises a first electrode and a second electrode, and the second PCM switch comprises a third electrode and a fourth electrode, wherein the second electrode is electrically connected to the third electrode to form a common electrical node; and
electrically connecting a radio-frequency (RF) antenna to the common electrical node.

2. The method of claim 1, wherein:
a first subset of the metal interconnect structures provides a first electrically conductive path between the first electrode and an output node of the power amplifier; and
a second subset of the metal interconnect structures provides a second electrically conductive path between the fourth electrode and an input node of the power amplifier.

3. The method of claim 2, wherein:
the output node of the power amplifier is the only electrical node of the semiconductor circuit to which the first electrode is electrically connected; and
the input node of the low noise amplifier is the only electrical node of the semiconductor circuit to which the fourth electrode is electrically connected.

4. The method of claim 1, further comprising:
depositing at least one metallic material layer over a topmost surface of the first dielectric material layers; and
patterning the at least one metallic material layer, wherein patterned portions of the at least one metallic material layer comprise a first heater element, a second heater element, the first electrode, the second electrode, the third electrode, and the fourth electrode.

5. The method of claim 4, wherein:
one of the patterned portions of the at least one metallic material layer comprises a metallic plate; and
the second electrode and the third electrode are formed as the metallic plate.

6. The method of claim 5, further comprising:
forming second dielectric material layers over the first PCM switch and the second PCM switch; and
forming a metallic via structure through a bottommost layer among the second dielectric material layers on a top surface of the metallic plate, wherein the RF antenna is electrically connected to the metallic plate through the metallic via structure.

7. The method of claim 4, further comprising:
depositing a phase change material layer over the first electrode, the first heater element, the second electrode, the third electrode, the second heater element, and the fourth electrode; and
patterning the phase change material layer, wherein a first patterned portion of the phase change material extends over the first electrode, the first heater element, and the second electrode, and a second patterned portion of the phase change material extends over the third electrode, the second heater element, and the fourth electrode.

8. The method of claim 7, wherein the first patterned portion of and the second patterned portion are formed as a respective portion of a single continuous phase change material portion that extends over each of the first heater element and the second heater element.

9. A method of forming a device structure, comprising:
forming a semiconductor circuit on a substrate;
forming a first metallic plate, a second metallic plate, a third metallic plate, a first heater element, and a second heater element on a topmost surface of first dielectric material layers, wherein the first heater element is formed between the first metallic plate and the second metallic plate, and the second heater element is formed between the second metallic plate and the third metallic plate; and
forming a first phase change material (PCM) switch and a second PCM switch over the first dielectric material layers, wherein the second metallic plate is a common electrode of the first PCM switch and the second PCM switch.

10. The method of Clam 9, wherein:
the semiconductor circuit comprises a power amplifier and a low noise amplifier; and
the first metallic plate is electrically connected to an output node of the power amplifier and the third metallic plate is electrically connected to an input node of the low noise amplifier.

11. The method of claim 10, further comprising forming metal interconnect structures within first dielectric material layers over the power amplifier and the low noise amplifier, wherein:
a first subset of the metal interconnect structures provides a first electrically conductive path between the first metallic plate and an output node of the power amplifier; and
a second subset of the metal interconnect structures provides a second electrically conductive path between the third metallic plate and an input node of the power amplifier.

12. The method of claim 9, further comprising:
depositing a phase change material layer over the first metallic plate, the second metallic plate, the third metallic plate, the first heater element, and the second heater element; and
patterning the phase change material layer, wherein a first patterned portion of the phase change material extends over the first metallic plate, the first heater element, and a first portion of the second metallic plate, and a second patterned portion of the phase change material extends over a second portion of the second metallic plate, the second heater element, and the third metallic plate, wherein the first patterned portion of and the second patterned portion are formed as a respective portion of a single continuous phase change material portion that extends over each of the first heater element and the second heater element.

13. The method of claim 9, further comprising:
forming second dielectric material layers over the first PCM switch and the second PCM switch;
forming a metallic via structure through a bottommost layer among the second dielectric material layers directly on a top surface of one of the first metallic plate, the second metallic plate, or the third metallic plate; and
electrically connecting a radio-frequency (RF) antenna to the metallic via structure by forming the RF antenna over the second dielectric material layers or by attaching a structure including the RF antenna to an assembly containing the substrate, the first dielectric material layers, and the second dielectric material layers.

14. A device structure comprising:
a semiconductor device including a power amplifier and a low noise amplifier and overlying a substrate;
an interconnect structure overlying the power amplifier and the low noise amplifier;
a first phase change material (PCM) switch and a second PCM switch located over the interconnect structure, wherein the first PCM switch comprises a first electrode and a second electrode, and the second PCM switch comprises a third electrode and a fourth electrode, wherein the second electrode is electrically connected to the third electrode to provide a common electrical node; and
a radio-frequency (RF) antenna electrically connected to the common electrical node.

15. The device structure of claim 14, wherein:
the first PCM switch comprises a first heater element located between the first electrode and the second electrode;
the second PCM switch comprises a second heater element located between the third electrode and the fourth electrode; and
each of the first heater element and the second heater element comprises a same set of at least one metallic material as the first electrode.

16. The device structure of claim 15, wherein:
the first PCM switch comprises a first phase change material portion;
the second PCM switch comprises a second phase change material portion; and
the first phase change material portion and the second phase change material portion are respective portions of a single continuous phase change material portion that extends over each of the first heater element and the second heater element.

17. The device structure of claim 16, wherein the single continuous phase change material portion laterally extends along a first horizontal direction with a substantially uniform width along a second horizontal direction, and contacts top surfaces of the first electrode, the second electrode, the third electrode, and the fourth electrode.

18. The device structure of claim 14, wherein the second electrode and the third electrode are formed as a single metallic plate.

19. The device structure of claim 18, further comprising:
second dielectric material layers over the first PCM switch and the second PCM switch; and
a metallic via structure vertically extending through a bottommost layer among the second dielectric material layers and contacting a top surface of the single metallic plate, wherein the RF antenna is electrically connected to the single metallic plate through the metallic via structure.

20. The device structure of claim 14, wherein:
a first subset of the interconnect structures provides a first electrically conductive path between the first electrode and an output node of the power amplifier;
a second subset of the interconnect structures provides a second electrically conductive path between the fourth electrode and an input node of the power amplifier;
the output node of the power amplifier is the only electrical node of the semiconductor circuit to which the first electrode is electrically connected; and
the input node of the low noise amplifier is the only electrical node of the semiconductor circuit to which the fourth electrode is electrically connected.
